(19) United States
(12) Patent Application Publication
(10) Pub. No.: US 2026/0150539 A1
(43) Pub. Date: May 28, 2026

(54) DISPLAY PANEL AND ELECTRONIC APPARATUS

(71) Applicant: Samsung Display Co., Ltd., Yongin-Si (KR)

(72) Inventors: Daehyun Kim, Yongin-si (KR); Jihyun Ka, Yongin-si (KR); Changkyu Jin, Yongin-si (KR); Minki Yang, Yongin-si (KR); Junghun Yi, Yongin-si (KR)

(21) Appl. No.: 19/400,083

(22) Filed: Nov. 25, 2025

(30) Foreign Application Priority Data
Nov. 26, 2024 (KR) 10-2024-0171478
Mar. 10, 2025 (KR) 10-2025-0030733

(51) Int. Cl. H10K 59/131; H10K 59/121; H10K 59/126

(52) U.S. Cl. CPC H10K 59/131; H10K 59/1213; H10K 59/1216; H10K 59/126

(57) ABSTRACT

A display panel includes a first voltage line connected to a first pixel circuit arranged in a first circuit area and a second pixel circuit arranged in a second circuit area, the first voltage line extending in a first direction, a first data line connected to the first pixel circuit and extending in a second direction perpendicular to the first direction, a second data line connected to the second pixel circuit and extending in the second direction, and a shield portion arranged between the first voltage line and the first data line and overlapping the first data line and the second data line in an area where the first data line and the second data line overlap the first voltage line.

### CROSS-REFERENCE TO RELATED APPLICATION

This application is based on and claims priority, under 35 U.S.C. § 119, to Korean Patent Application No. 10-2024-0171478 filed on Nov. 26, 2024 and Korean Patent Application No. 10-2025-0030733 filed on Mar. 10, 2025 in the Korean Intellectual Property Office, the disclosures of which are incorporated by reference herein in their entirety.

### BACKGROUND

### 1. Field

One or more embodiments relate to a display panel and an electronic apparatus.

### 2. Description of the Related Art

Recently, display apparatuses have been used for various purposes. As display apparatuses have become thinner and lighter, their range of use has broadened.

As display apparatuses are used in more diverse ways, various methods may be used to design the shapes of display apparatuses, and further, more functions may be combined or associated with display apparatuses.

### SUMMARY

One or more embodiments include high-resolution display apparatuses. However, these effects are merely examples and the scope of the disclosure is not limited thereto.

Additional aspects will be set forth in part in the description which follows and, in part, will be apparent from the description, or may be learned by practice of the presented embodiments of the disclosure.

According to one or more embodiments, a display panel includes a substrate having a first circuit area and a second circuit area adjacent to the first circuit area, a first voltage line connected to a first pixel circuit arranged in the first circuit area and a second pixel circuit arranged in the second circuit area, the first voltage line extending in a first direction, a first data line connected to the first pixel circuit and extending in a second direction perpendicular to the first direction, a second data line connected to the second pixel circuit and extending in the second direction, and a shield portion arranged between the first voltage line and the first data line and overlapping the first data line and the second data line in an area where the first data line and the second data line overlap the first voltage line. In a plan view, the first data line and the second data line are arranged apart from each other, a boundary between the first circuit area and the second circuit area extending between the first data line and the second data line and parallel to the first data line.

In an embodiment, in a plan view, the first pixel circuit and the second pixel circuit may be symmetrical with respect to the boundary between the first circuit area and the second circuit area.

In an embodiment, the display panel may further include a second voltage line connected to the first pixel circuit and the second pixel circuit, arranged in a layer between the first voltage line and the first data line, and extending in the first direction, wherein the shield portion may be a portion of the second voltage line, and each of a first voltage supplied to the first voltage line and a second voltage supplied to the second voltage line may be a constant voltage.

In an embodiment, the display panel may further include a third data line connected to a third pixel circuit arranged in a third circuit area adjacent to the first circuit area, the third data line extending in the second direction, wherein the first voltage line may be connected to the third pixel circuit, and the first circuit area may be arranged between the third circuit area and the second circuit area. In a plan view, the first data line and the third data line may be arranged in parallel to and apart from each other, a driving transistor of the first pixel circuit and a driving transistor of the third pixel circuit being between the first data line and the third data line, and in a plan view, the first data line and the second data line may be arranged between a driving transistor of the first pixel circuit and a driving transistor of the second pixel circuit.

In an embodiment, in a plan view, the first pixel circuit and the third pixel circuit may be symmetrical with respect to a boundary between the first circuit area and the third circuit area.

In an embodiment, the display panel may further include a vertical voltage line arranged on a boundary between the first circuit area and the third circuit area and connected to the first voltage line.

In an embodiment, the display panel may further include at least one shared voltage line arranged in the first circuit area and the second circuit area, respectively, in a plan view and extending in the second direction, wherein the shared voltage line may be arranged on a side of at least one of the first data line and the second data line that is not occupied by the other one of the first data line and the second data line, and the shared voltage line may be connected to at least one third voltage line connected to the first pixel circuit, the second pixel circuit, and the third pixel circuit.

In an embodiment, the first pixel circuit may include a driving transistor, a first transistor comprising a first terminal connected to the first data line, a second transistor comprising a first terminal connected to the first voltage line, a first capacitor connected between a gate electrode of the driving transistor and a second terminal of the first transistor; and a second capacitor connected between the first capacitor and a driving voltage line, wherein a second terminal of the second transistor is connected to a second terminal of the first transistor.

In an embodiment, the shield portion may be a portion of the driving voltage line, and each of a first voltage supplied to the first voltage line and a driving voltage supplied to the driving voltage line is a constant voltage.

In an embodiment, wherein, after the first voltage supplied to the first voltage line is supplied through the second transistor to a node to which the second terminal of the second transistor and the second terminal of the first transistor are connected, a data signal supplied to the first data line is supplied to the node through the first transistor.

According to one or more embodiments, a display panel includes a substrate having a first circuit area and a second circuit area adjacent to the first circuit area, a first voltage line connected to a first pixel circuit arranged in the first circuit area and a second pixel circuit arranged in the second circuit area, the first voltage line extending in a first direction, a first data line connected to the first pixel circuit and extending in a second direction perpendicular to the first direction, a second data line connected to the second pixel circuit and extending in the second direction, and a vertical voltage line arranged on a boundary between the first circuit area and the second circuit area and connected to the first voltage line. In a plan view, a driving transistor of the first pixel circuit is arranged between the first data line and the vertical voltage line, and a driving transistor of the second pixel circuit is arranged between the vertical voltage line and the second data line.

In an embodiment, in a plan view, the first pixel circuit and the second pixel circuit may be symmetrical with respect to the boundary between the first circuit area and the second circuit area.

In an embodiment, the display panel may further include a third data line connected to a third pixel circuit arranged in a third circuit area adjacent to the second circuit area, the third data line extending in the second direction, wherein the first voltage line may be connected to the third pixel circuit, the second circuit area may be arranged between the first circuit area and the third circuit area, and in a plan view, the second data line and the third data line may be arranged apart from each other between a driving transistor of the second pixel circuit and a driving transistor of the third pixel circuit.

In an embodiment, the display panel may further include a first shield portion arranged between the first voltage line and the first data line and overlapping the first voltage line and the first data line, and a second shield portion arranged between the first voltage line and the second data line and overlapping the first voltage line, the second data line, and the third data line.

In an embodiment, the display panel may further include a second voltage line connected to the first pixel circuit, the second pixel circuit, and the third pixel circuit, and arranged in a layer between the first voltage line and the first data line, and extending in the first direction, wherein the first shield portion and the second shield portion may be portions of the second voltage line, and each of a first voltage supplied to the first voltage line and a second voltage supplied to the second voltage line may be a constant voltage.

In an embodiment, in a plan view, the second pixel circuit and the third pixel circuit may be symmetrical with respect to a boundary between the second circuit area and the third circuit area.

In an embodiment, the display panel may further include at least one shared voltage line in at least one of the second circuit area and the third circuit area in a plan view and extending in the second direction, wherein the shared voltage line may be arranged on a side of at least one of the second data line and the third data line that is not occupied by the other one of the second data line and the third data line, and the shared voltage line may be connected to at least one third voltage line connected to the first pixel circuit, the second pixel circuit, and the third pixel circuit.

According to one or more embodiments, a display panel includes a first voltage line connected to a pixel circuit, a data line connected to the pixel circuit, arranged on the first voltage line, and at least partially overlapping the first voltage line, and a shield portion arranged between the first voltage line and the data line and overlapping the data line in an area where the data line and the first voltage line overlap each other.

In an embodiment, the pixel circuit may include a driving transistor, a first transistor including a first terminal connected to the data line, a second transistor including a first terminal connected to the first voltage line, a first capacitor connected between a gate electrode of the driving transistor and a second terminal of the first transistor, and a second capacitor connected between the first capacitor and a driving voltage line, wherein a second terminal of the second transistor may be connected to a second terminal of the first transistor.

In an embodiment, the shield portion may be a portion of the driving voltage line, and each of a first voltage supplied to the first voltage line and a driving voltage supplied to the driving voltage line may be a constant voltage.

In an embodiment, after the first voltage supplied to the first voltage line is supplied through the second transistor to a node to which the second terminal of the second transistor and the second terminal of the first transistor are connected, a data signal supplied to the data line may be supplied to the node through the first transistor.

According to one or more embodiments, an electronic apparatus includes a controller configured to receive an on-operation signal from a processor and output a control signal based on the on-operation signal, a gate driver configured to receive the control signal and sequentially output at least one gate signal, and a display panel in which a plurality of pixels receiving the at least one gate signal are arranged, wherein each of the plurality of pixels includes a pixel circuit and a light emitting element connected to the pixel circuit. The display panel includes a substrate in which a first circuit area and a second circuit area adjacent to the first circuit area are defined, a first voltage line connected to a first pixel circuit arranged in the first circuit area and a second pixel circuit arranged in the second circuit area, the first voltage line extending in a first direction, a first data line connected to the first pixel circuit and extending in a second direction perpendicular to the first direction, a second data line connected to the second pixel circuit and extending in the second direction, and a shield portion arranged between the first voltage line and the first data line and overlapping the first data line and the second data line in an area where the first data line and the second data line overlap the first voltage line, wherein, in a plan view, the first data line and the second data line are arranged apart from each other, a boundary between the first circuit area and the second circuit area extending between the first data line and the second data line and parallel to the first data line.

In an embodiment, the display panel may further include a third data line connected to a third pixel circuit arranged in a third circuit area adjacent to the first circuit area, the third data line extending in the second direction, wherein the first voltage line may be connected to the third pixel circuit, the first circuit area may be arranged between the third circuit area and the second circuit area, in a plan view, the first data line and the third data line may be arranged in parallel to and apart from each other, a driving transistor of the first pixel circuit and a driving transistor of the third pixel circuit being between the first data line and the third data line, and in a plan view, the first data line and the second data line may be arranged between a driving transistor of the first pixel circuit and a driving transistor of the second pixel circuit.

In an embodiment, the display panel may further include a vertical voltage line arranged on a boundary between the first circuit area and the third circuit area and connected to the first voltage line.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A and 1B are diagrams schematically illustrating a display apparatus according to an embodiment;

FIG. 2 is a diagram schematically illustrating a display apparatus according to an embodiment;

FIG. 3 is a schematic equivalent circuit diagram of a pixel according to an embodiment;

FIG. 4 is a timing diagram describing an operation of the pixel of FIG. 3 according to an embodiment;

FIG. 5 is a diagram illustrating a distortion of a reference voltage according to an operation of pixels;

FIGS. 6 to 9 are diagrams illustrating a relationship between a data line and a reference voltage line according to an embodiment;

FIG. 10 is a diagram illustrating a reference voltage according to an operation of pixels according to an embodiment;

FIGS. 11 and 12 are diagrams illustrating a relationship between a data line and a reference voltage line according to an embodiment;

FIG. 13 is an arrangement diagram schematically illustrating circuit elements of the pixel of FIG. 3;

FIGS. 14 to 21 are arrangement diagrams schematically illustrating, on a layer-by-layer basis, circuit elements of the pixel of FIG. 3;

FIG. 22 is a cross-sectional view of the pixel taken along lines I-I′, II-II′, and III-III′ of FIG. 13;

FIGS. 23 to 25 are diagrams schematically illustrating a reference voltage line according to an embodiment;

FIGS. 26 and 27 are arrangement diagrams schematically illustrating circuit elements of the pixel of FIG. 3 according to an embodiment;

FIGS. 28 and 29 are diagrams schematically illustrating an arrangement of a display element according to an embodiment;

FIG. 30 is a diagram schematically illustrating a display element according to an embodiment;

FIGS. 31 to 35 are equivalent circuit diagrams of a pixel according to an embodiment;

FIGS. 36 and 37 are diagrams schematically illustrating a portion of a pixel according to an embodiment;

FIG. 38 is a block diagram of an electronic apparatus according to an embodiment; and

FIG. 39 is a schematic diagram of electronic apparatuses according to various embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are described below by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure may include various embodiments and modifications, and particular embodiments thereof are illustrated in the drawings and will be described herein in detail. The effects and features of the disclosure and methods of achieving them will become apparent with reference to the embodiments described below in detail together with the drawings. However, the disclosure is not limited to the embodiments described below and may be implemented in various forms.

It will be understood that although terms such as “first” and “second” may be used herein to describe various elements, these elements should not be limited by these terms and these terms are only used to distinguish one element from another element.

As used herein, the singular forms “a,” “an,” and “the” are intended to include the plural forms as well, unless the context clearly indicates otherwise.

It will be understood that terms such as “comprise,” “include,” and “have” used herein specify the presence of stated features or elements, but do not preclude the presence or addition of one or more other features or elements.

It will be understood that when a layer, region, or element is referred to as being “on” another layer, region, or element, it may be “directly on” the other layer, region, or element or may be “indirectly on” the other layer, region, or element with one or more intervening layers, regions, or elements therebetween.

As used herein, “A and/or B” represents the case of A, B, or A and B. Also, herein, “at least one of A and B” represents the case of A, B, or A and B.

In the following embodiments, when X and Y are connected to each other, X and Y may be electrically connected to each other, X and Y may be functionally connected to each other, or X and Y may be physically connected to each other. Here, X and Y may be objects (e.g., apparatuses, devices, elements, circuits, lines, electrodes, terminals, conductive layers, or layers). Thus, the disclosure is not limited to a certain connection relationship, for example, a connection relationship indicated in the drawings or the detailed description, and may also include anything other than the connection relationship indicated in the drawings or the detailed description.

For example, when X and Y are electrically connected to each other, X and Y may be electrically connected to each other while directly contacting each other or one or more devices (e.g., switches, transistors, capacitors, inductors, resistors, or diodes) enabling the electrical connection between X and Y may be connected between X and Y.

In the following embodiments, when used in relation to a state of a device, “on” may refer to an activated state of the device and “off” may refer to a deactivated state of the device. When used in relation to a signal received by a device, “on” may refer to a signal for activating the device and “off” may refer to a signal for deactivating the device. A device may be activated by a high-level voltage or a low-level voltage. For example, a P-channel transistor (P-type transistor) may be activated by a low-level voltage, and an N-channel transistor (N-type transistor) may be activated by a high-level voltage. Thus, it should be understood that “on” voltages for the P-type transistor and the N-type transistor have opposite (low versus high) voltage levels.

Also, herein, the x direction, the y direction, and the z direction are not limited to the directions along three axes of the rectangular coordinate system and may be interpreted in a broader sense. For example, the x direction, the y direction, and the z direction may be perpendicular to one another or may represent different directions that are not perpendicular to one another.

Herein, when a certain embodiment may be implemented differently, a particular process order may be performed differently from the described order. For example, two consecutively described processes may be performed substantially at the same time or performed in an order opposite to the described order.

Sizes of elements in the drawings may be exaggerated for convenience of description. In other words, because the sizes and shapes of elements in the drawings are arbitrarily illustrated for convenience of description, the disclosure is not limited thereto.

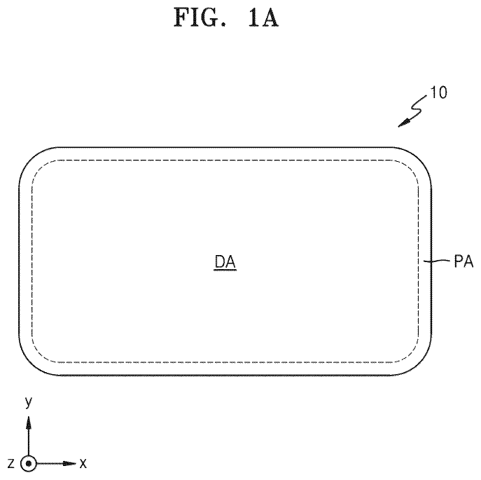

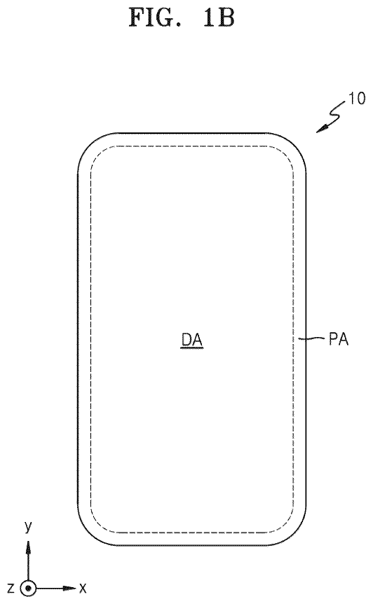

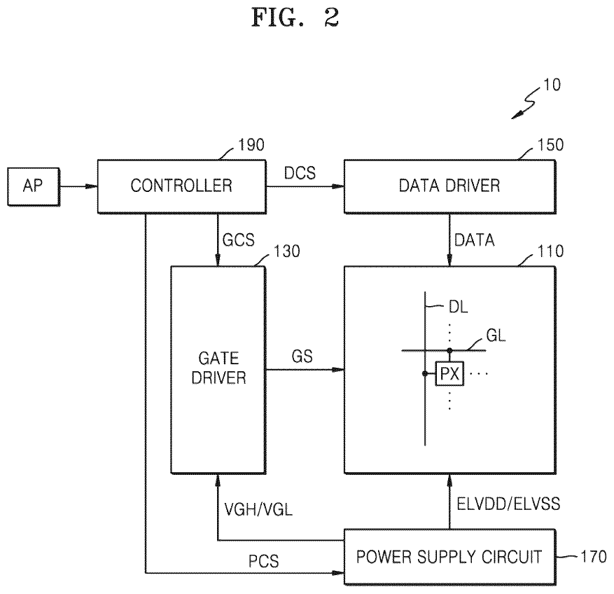

FIGS. 1A and 1B are diagrams schematically illustrating a display apparatus according to an embodiment. FIG. 2 is a diagram schematically illustrating the display apparatus according to an embodiment.

Referring to FIGS. 1A and 1B, a display apparatus 10 may include a display area DA displaying an image and a peripheral area PA outside the display area DA. The display area DA may be entirely surrounded by the peripheral area PA.

In a plan view, the display area DA may have a rectangular shape. In other embodiments, the display area DA may have a polygonal shape such as a triangular, pentagonal, or hexagonal shape, a circular shape, an elliptical shape, an atypical shape, or the like. A corner of an edge of the display area DA may be rounded. In an embodiment as illustrated in FIG. 1A, the display apparatus 10 may include a display area DA having a shape in which a length in the x direction is greater than a length in the y direction. In another embodiment as illustrated in FIG. 1B, the display apparatus 10 may include a display area DA having a shape in which a length in the y direction is greater than the length in the x direction.

The display apparatus 10 may display moving images or still images and may visually provide information to the user. The display apparatus 10 according to an embodiment may be a display apparatus such as an organic light emitting display apparatus, an inorganic light emitting display apparatus (or inorganic EL display apparatus), or a quantum dot light emitting display apparatus.

Referring to FIG. 2, the display apparatus 10 may include a display panel 110. The display panel 110 may include a substrate, and a plurality of gate lines GL, a plurality of data lines DL, and a plurality of pixels PX connected thereto may be arranged in a display area DA of the substrate. The plurality of pixels PX may be repeatedly arranged in a first direction (x direction or row direction) and a second direction (y direction or column direction). Each of the plurality of pixels PX may include an organic light emitting diode as a display element, and the organic light emitting diode may be connected to a pixel circuit. The pixel circuit may include a plurality of transistors and at least one capacitor. Each pixel PX may be connected to at least one corresponding gate line among the plurality of gate lines GL and a corresponding data line among the plurality of data lines DL.

Each of the gate lines GL may extend in the x direction (row direction) to be connected to the pixels PX located in the same row. Each of the gate lines GL may be configured to transmit a gate signal to the pixels PX in the same row. Each of the data lines DL may extend in the y direction (column direction) to be connected to the pixels PX located in the same column. Each of the data lines DL may be configured to transmit a data signal to each of the pixels PX in the same column in synchronization with a gate signal.

Various conductive lines for transmitting electrical signals to be applied to the display area DA, peripheral driving circuits electrically connected to pixel circuits, and/or pads to which a printed circuit board or a driver IC chip is attached may be located in a peripheral area (non-display area) PA outside the display area DA of the display panel 110. The peripheral driving circuits may include a gate driver 130, a data driver 150, a power supply circuit 170, and a controller 190.

In an embodiment, the gate driver 130, the data driver 150, the power supply circuit 170, and the controller 190 may be mounted on the display panel 110 as a driving chip. Each of the data driver 150, the power supply circuit 170, and the controller 190 may be formed in a separate integrated circuit chip or a single integrated circuit chip and arranged over a flexible printed circuit board (FPCB) electrically connected to a pad arranged on one side of the substrate. In other embodiments, the data driver 150, the power supply circuit 170, and the controller 190 may be directly arranged over the substrate by using a chip-on-glass (COG) or chip-on-plastic (COP) method.

The gate driver 130 may be connected to a plurality of gate lines GL, may generate a gate signal GS in response to a gate driving control signal GCS from the controller 190, and may sequentially supply the gate signal to the gate lines GL. The gate line GL may be connected to a gate of the transistor included in the pixel PX, and the gate signal GS may be a gate control signal for controlling the turn-on and turn-off of a transistor to which a gate line is connected. The gate signal GS may include a gate-on voltage at which the transistor may be turned on and a gate-off voltage at which the transistor may be turned off. In an embodiment, the gate driving control signal GCS may include a start signal and a plurality of clock signals. In an embodiment, the gate driver 130 may be arranged on the left side and/or right side of the display area DA.

The data driver 150 may be connected to a plurality of data lines DL and may generate data signals DATA in response to a data driving control signal DCS from the controller 190. The data signals DATA may be transmitted to the pixel circuits of the pixels PX through the data lines DL. The data signal DATA input to the data line DL may be input to the pixel PX to which a gate signal is input. The data driver 150 may convert input image data with gradation input from the controller 190, into a data signal DATA in the form of a voltage or current. In an embodiment, the data driving control signal DCS may include a start signal and a plurality of clock signals.

The power supply circuit 170 may generate signals (voltage and current) necessary for driving the pixels PX, in response to a power driving control signal PCS from the controller 190.

When the display apparatus 10 is an organic light emitting display apparatus, the power supply circuit 170 may supply a first driving voltage ELVDD and a second driving voltage ELVSS. The first driving voltage ELVDD may be applied to the pixel circuits of the pixel PX through a driving voltage line arranged in the display area DA, and the second driving voltage ELVSS may be applied to an opposite electrode of the display element. The first driving voltage ELVDD may be a high-level voltage provided to one terminal of a driving transistor connected to a first electrode (pixel electrode or anode) of an organic light emitting diode included in the pixel PX. The second driving voltage ELVSS may be a low-level voltage provided to a second electrode (opposite electrode or cathode) of the organic light emitting diode. The first driving voltage ELVDD and the second driving voltage ELVSS may be driving voltages for emitting light of the plurality of pixels PX.

The power supply circuit 170 may generate a high-level voltage VGH and a low-level voltage VGL and supply the same to the gate driver 130.

The controller 190 may generate a gate driving control signal GCS, a data driving control signal DCS, and a power driving control signal PCS based on the signals input from the outside. The controller 190 may supply the gate driving control signal GCS to the gate driver 130, supply the data driving control signal DCS to the data driver 150, and supply the power driving control signal PCS to the power supply circuit 170.

In an embodiment, the display apparatus 10 may be connected to a processor of an electronic apparatus. The processor may include an application processor AP. The controller 190 may receive an on-operation signal, for example, a power-on signal and/or an operation flag signal, from the application processor AP. When the electronic apparatus is powered on by the user or is awoken from a sleep mode, the controller 190 may receive an on-operation signal from the application processor AP and generate and output a gate driving control signal GCS, a data driving control signal DCS, and a power driving control signal PCS based on the on-operation signal.

In an embodiment, a portion or all of the gate driver 130 may be directly formed in a peripheral area of the substrate in the process of forming transistors constituting a pixel circuit in the display area of the substrate. The gate driver 130 may include an amorphous silicon TFT gate driver circuit (ASG), a low-temperature polycrystalline silicon (LTPS) TFT gate driver circuit, or an oxide semiconductor TFT gate driver circuit (OSG) embedded in the display panel 110.

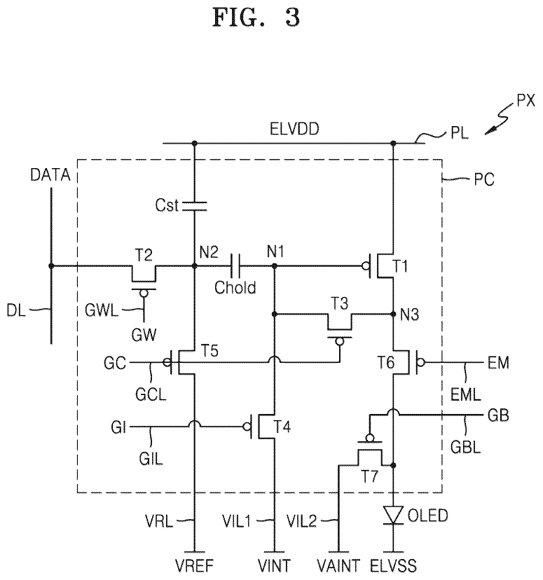

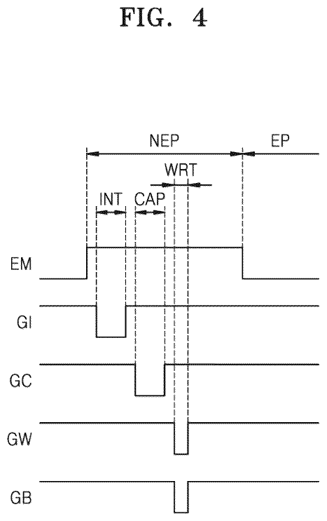

FIG. 3 is a schematic equivalent circuit diagram of a pixel according to an embodiment. FIG. 4 is a timing diagram describing an operation of the pixel of FIG. 3 according to an embodiment.

Referring to FIG. 3, a pixel PX may include a pixel circuit PC and an organic light emitting diode OLED as a display element connected to the pixel circuit PC.

The pixel circuit PC may include first to seventh transistors T1 to T7, a first capacitor Cst, and a second capacitor Chold. Signal lines connected to the pixel circuit PC may include a data line DL, a first gate line GWL, a second gate line GIL, a third gate line GCL, a fourth gate line EML, a fifth gate line GBL, a driving voltage line PL, a reference voltage line VRL, a first initialization voltage line VIL1, and a second initialization voltage line VIL2. The reference voltage line VRL may herein be referred to as a “first voltage line.” The driving voltage line PL may herein be referred to as a “second voltage line.”

The first transistor T1 may be a driving transistor whose source-drain current is determined according to a gate-source voltage (Vgs), and the second to seventh transistors T2 to T7 may be switching transistors that are turned on/off according to a gate-source voltage, substantially a gate voltage. The first to seventh transistors T1 to T7 may be thin film transistors. Depending on the transistor type (P-type or N-type) and/or operation condition, a first terminal of each of the first to seventh transistors T1 to T7 may be a source or a drain and a second terminal thereof may be a terminal different from the first terminal. For example, when the first terminal is a source, the second terminal may be a drain.

In an embodiment, the first to seventh transistors T1 to T7 may be P-channel transistors. In an embodiment, the P-channel transistor may be a silicon thin film transistor including a silicon semiconductor. The semiconductor of the silicon thin film transistor may include amorphous silicon, polysilicon, or the like. A gate-on voltage of a gate signal for turning on the P-channel transistor may be a low-level voltage (first-level voltage), and a gate-off voltage of a gate signal for turning off the P-channel transistor may be a high-level voltage (second-level voltage).

The first transistor T1 may be connected between the driving voltage line PL and the organic light emitting diode OLED. The first transistor T1 may be connected between the driving voltage line PL and a third node N3. The first transistor T1 may be connected to the organic light emitting diode OLED via the sixth transistor T6. The first transistor T1 may include a gate connected to a first node N1, a first terminal connected to the driving voltage line PL, and a second terminal connected to the third node N3. The first transistor T1 may supply, to the organic light emitting diode OLED, a driving current corresponding to a voltage applied to the first node N1.

The second transistor T2 may be connected between the data line DL and a second node N2. The second transistor T2 may include a gate connected to the first gate line GWL, a first terminal connected to the data line DL, and a second terminal connected to the second node N2. The second transistor T2 may be turned on by a first gate signal GW received through the first gate line GWL, to transmit a data signal DATA received through the data line DL to the second node N2.

The third transistor T3 may be connected to the first node N1 and the third node N3. The third transistor T3 may include a gate connected to the third gate line GCL, a first terminal connected to the first node N1, and a second terminal connected to the third node N3. When the third transistor T3 is turned on by a third gate signal GC received through the third gate line GCL, the first transistor T1 may be diode-connected. When the first transistor T1 is diode-connected, the threshold voltage of the first transistor T1 may be compensated.

The fourth transistor T4 may be connected to the first node N1 and the first initialization voltage line VIL1. The fourth transistor T4 may include a gate connected to the second gate line GIL, a first terminal connected to the first node N1, and a second terminal connected to the first initialization voltage line VIL1. The fourth transistor T4 may be turned on by a second gate signal GI received through the second gate line GIL, to transmit a first initialization voltage VINT to the first node N1 to initialize the first node N1, that is, the gate of the first transistor T1.

The fifth transistor T5 may be connected to the second node N2 and the reference voltage line VRL. The fifth transistor T5 may include a gate connected to the third gate line GCL, a first terminal connected to the second node N2, and a second terminal connected to the reference voltage line VRL. The fifth transistor T5 may be turned on by a third gate signal GC received through the third gate line GCL, to transmit a reference voltage VREF to the second node N2.

The sixth transistor T6 may be connected to the third node N3 and the organic light emitting diode OLED. The sixth transistor T6 may include a gate connected to the fourth gate line EML, a first terminal connected to the third node N3, and a second terminal connected to the organic light emitting diode OLED. The second terminal of the sixth transistor T6 may be connected to a pixel electrode of the organic light emitting diode OLED. When the sixth transistor T6 is turned on by a fourth gate signal EM received through the fourth gate line EML, a driving current may flow through the organic light emitting diode OLED.

The seventh transistor T7 may be connected to the organic light emitting diode OLED and the second initialization voltage line VIL2. The seventh transistor T7 may include a gate connected to the fifth gate line GBL, a first terminal connected to the pixel electrode, and a second terminal connected to the second initialization voltage line VIL2. The seventh transistor T7 may be configured to transmit a second initialization voltage VAINT to the pixel electrode to initialize the pixel electrode.

The first capacitor Cst may be connected to the driving voltage line PL and the second node N2. The first capacitor Cst may store a voltage corresponding to the voltage difference between the driving voltage line PL and the second node N2.

The second capacitor Chold may be connected to the first node N1 and the second node N2. The second capacitor Chold may store a voltage corresponding to the voltage difference between the first node N1 and the second node N2.

The organic light emitting diode OLED may include a pixel electrode (e.g., anode) and an opposite electrode (e.g., cathode) facing the pixel electrode, and the opposite electrode may receive a second driving voltage ELVSS. The organic light emitting diode OLED may receive a driving current corresponding to the data signal DATA from the first transistor T1 to emit light in a certain color to display an image.

Referring to FIG. 4, the gate driver 130 may supply first to fifth gate signals GW, GI, GC, EM, and GB to the first to fifth gate lines GWL, GIL, GCL, EML, and GBL respectively. The power supply circuit 170 may supply a first driving voltage ELVDD to the driving voltage line PL, a second driving voltage ELVSS to the opposite electrode, a reference voltage VREF to the reference voltage line VRL, a first initialization voltage VINT to the first initialization voltage line VIL1, and a second initialization voltage VAINT to the second initialization voltage line VIL2.

Referring to FIG. 4, a period in which the fourth gate signal EM is a gate-off voltage may be a non-emission period NEP, and a period in which the fourth gate signal EM is a gate-on voltage may be an emission period EP. The non-emission period NEP may include at least one initialization period and at least one compensation period.

A first period INT may be an initialization period for initializing the first node N1 to which the gate of the first transistor T1 is connected. In the first period INT, a second gate signal GI of a gate-on voltage (first-level voltage) may be supplied from the gate driver 130 to the second gate line GIL. The fourth transistor T4 may be turned on by the second gate signal GI, and the gate of the first transistor T1 may be initialized by the first initialization voltage VINT.

A second period CAP may be a compensation period for compensating the threshold voltage of the first transistor T1. In the second period CAP, a third gate signal GC of a gate-on voltage may be supplied from the gate driver 130 to the third gate line GCL. The third transistor T3 and the fifth transistor T5 may be turned on by the third gate signal GC. The reference voltage VREF may be supplied to the second node N2 by the turned-on fifth transistor T5. The first transistor T1 may be diode-connected by the turned-on third transistor T3, and the voltage of the gate of the first transistor T1 in the diode-connected state may be ELVDD+Vth (Vth<0).

A third period WRT may be a write period (data programming period) in which a data signal is applied to the pixel PX. In the third period WRT, a first gate signal GW of a gate-on voltage may be supplied from the gate driver 130 to the first gate line GWL, and a fifth gate signal GB of a gate-on voltage may be supplied to the fifth gate line GBL. The second transistor T2 may be turned on by the first gate signal GW, and the data signal DATA supplied to the data line DL may be transmitted to the second node N2. Accordingly, the voltage of the second node N2 may change by a voltage corresponding to the difference between the reference voltage VREF and the data signal DATA, and the voltage of the first node N1 may also change corresponding to the amount of voltage change of the second node N2. Accordingly, the second capacitor Chold may be charged with a voltage corresponding to the data signal DATA and the threshold voltage (Vth) of the first transistor T1. The seventh transistor T7 may be turned on by the fifth gate signal GB, and the pixel electrode of the organic light emitting diode OLED may be initialized by the second initialization voltage VAINT. Thus, the third period WRT may be a period for initializing the pixel electrode of the organic light emitting diode OLED.

In the emission period EP, a fourth gate signal EM of a gate-on voltage may be supplied from the gate driver 130 to the fourth gate line EML. The sixth transistor T6 may be turned on by the fourth gate signal EM, and a current path from the driving voltage line PL to the organic light emitting diode OLED may be formed. The first transistor T1 may output a driving current corresponding to the data signal, and the organic light emitting diode OLED may emit light with a brightness corresponding to the driving current.

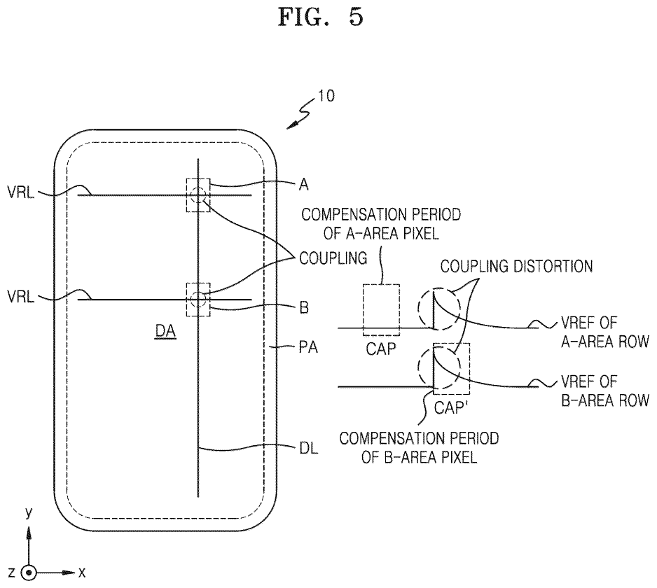

FIG. 5 is a diagram illustrating a distortion of a reference voltage according to an operation of pixels.

In an embodiment, data lines DL and reference voltage lines VRL may overlap each other. Referring to FIG. 5, the gate driver 130 may supply the third gate signal GC sequentially from the first row to the last row of the display area DA, and accordingly, compensation operations of the pixels of each row may be sequentially performed. The data driver 150 may transmit the data signal DATA to the data lines DL to which the pixels of a row to which the first gate signal GW is supplied are connected. When the data signal DATA is transmitted to the data line DL, the reference voltage VREF supplied to the reference voltage line VRL may be distorted due to a coupling with the data signal DATA in an area in which the data line DL and the reference voltage line VRL overlap each other. In the display area DA, a multi-line horizontal cross-talk may occur due to a distortion of the reference voltage VREF. For example, in the pixel of area A, the threshold voltage of the first transistor T1 may be compensated in the second period CAP that is a compensation period, and the data signal DATA may be written in the third period WRT. The third period WRT of the pixel of area A may overlap a second period CAP′ of the pixel of area B. When the data signal DATA is written into the pixel of area A, the reference voltage VREF may be distorted due to a coupling with the data signal DATA in area A and area B in which the data line DL and the reference voltage line VRL overlap each other. The pixel of area A may not be affected by the distortion of the reference voltage VREF in the second period CAP, but the pixel of area B may be affected by the distortion of the reference voltage VREF in the second period CAP′.

The disclosure may provide a method for preventing or minimizing the coupling effect caused by the overlap between the data line DL and the reference voltage line VRL.

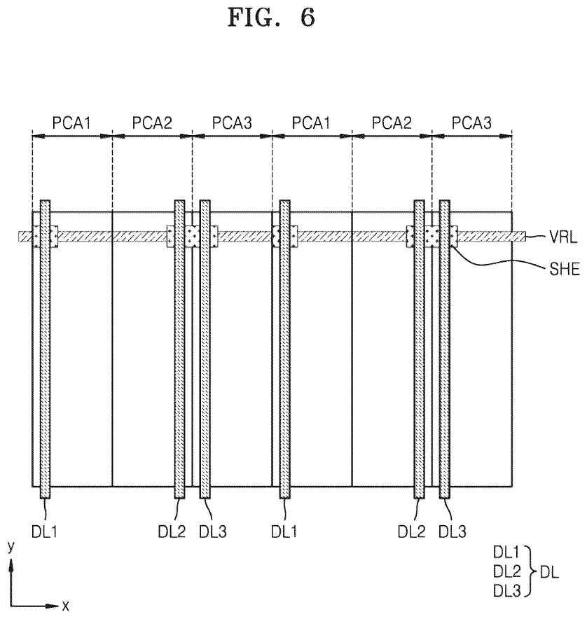

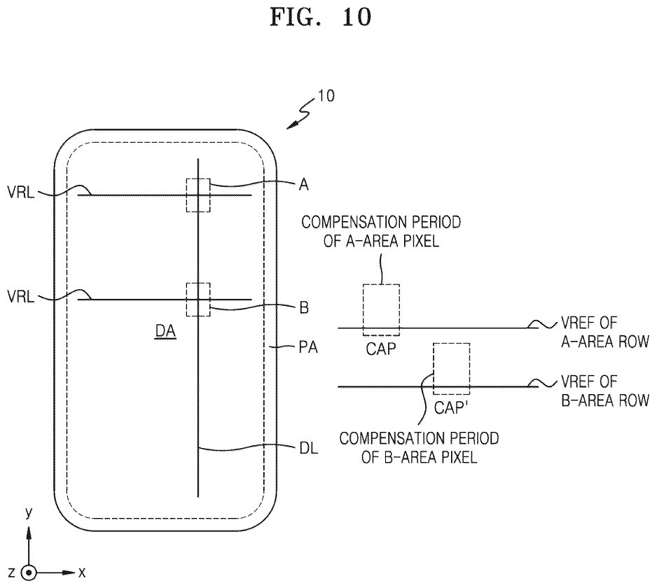

FIGS. 6 to 9 are diagrams illustrating the relationship between a data line and a reference voltage line according to an embodiment. FIG. 10 is a diagram illustrating a reference voltage according to an operation of pixels according to an embodiment.

Referring to FIG. 6, a display area DA defined in a substrate 100 may include a plurality of circuit areas, and a plurality of pixels may be arranged in the display area DA.

The plurality of pixels PX may include a first pixel emitting light in a first color, a second pixel emitting light in a second color, and a third pixel emitting light in a third color. For example, the first pixel may be a red pixel, the second pixel may be a green pixel, and the third pixel may be a blue pixel. Each of the first pixel, the second pixel, and the third pixel may include a pixel circuit and an organic light emitting diode OLED as a display element electrically connected to the pixel circuit.

The circuit area may be an area in which a row (pixel row) and a column (pixel column) intersect each other and may be an area in which a pixel circuit is arranged. In an embodiment, a unit circuit area including two or more circuit areas adjacent to each other in the first direction (x direction) may be defined in the substrate 100, and a unit pixel may be defined by the pixels arranged in the circuit areas constituting the unit circuit area. For example, the unit circuit area may include three circuit areas, that is, a first circuit area PCA1, a second circuit area PCA2, and a third circuit area PCA3 adjacent to each other in the first direction, and the unit pixel may include a first pixel, a second pixel, and a third pixel.

The first circuit area PCA1 may be an area in which a pixel circuit of the first pixel is arranged. The second circuit area PCA2 may be an area in which a pixel circuit of the second pixel is arranged. The third circuit area PCA3 may be an area in which a pixel circuit of the third pixel is arranged.

In an embodiment, a first data line DL1 connected to the pixel circuit of the first pixel may be arranged on one side (e.g., the left side) of the first circuit area PCA1, a second data line DL2 connected to the pixel circuit of the second pixel may be arranged on one side (e.g., the right side) of the second circuit area PCA2, and a third data line DL3 connected to the pixel circuit of the third pixel may be arranged on one side (e.g., the left side) of the third circuit area PCA3. The second data line DL2 and the third data line DL3 may be arranged adjacent to each other on the boundary between the second circuit area PCA2 and the third circuit area PCA3.

In an embodiment, the reference voltage line VRL may be connected to the pixel circuit of the first pixel, the pixel circuit of the second pixel, and the pixel circuit of the third pixel in the same row and may extend across the first circuit area PCA1, the second circuit area PCA2, and the third circuit area PCA3 in the first direction (x direction). In another embodiment, in each row, the reference voltage line VRL may include a plurality of sub-voltage lines that are provided in at least one circuit area unit and are spaced apart from each other. For example, the reference voltage line VRL may include a first sub-voltage line arranged in the first circuit area PCA1 and connected to the pixel circuit of the first pixel and a second sub-voltage line arranged in the second circuit area PCA2 and the third circuit area PCA3 and connected to the pixel circuit of the second pixel and the pixel circuit of the third pixel, and the first sub-voltage line and the second sub-voltage line may be spaced apart from each other. The length of the sub-voltage lines, that is, the number of circuit areas in which the sub-voltage lines are arranged, may be the same or different.

As illustrated in FIG. 6, in an embodiment, a shield portion SHE may be provided between the data line DL and the reference voltage line VRL in an area in which the data line DL and the reference voltage line VRL overlap each other. A constant voltage may be supplied to the shield portion SHE. By arranging the shield portion SHE between the data line DL and the reference voltage line VRL, a distortion of the reference voltage VREF due to the data signal DATA may be reduced. In an embodiment, the shield portion SHE may be an island-shaped conductive pattern (conductive electrode) or a portion of a conductive layer to which a constant voltage is transmitted. The island-shaped shield portion SHE may be connected to any conductive layer to which a constant voltage is transmitted.

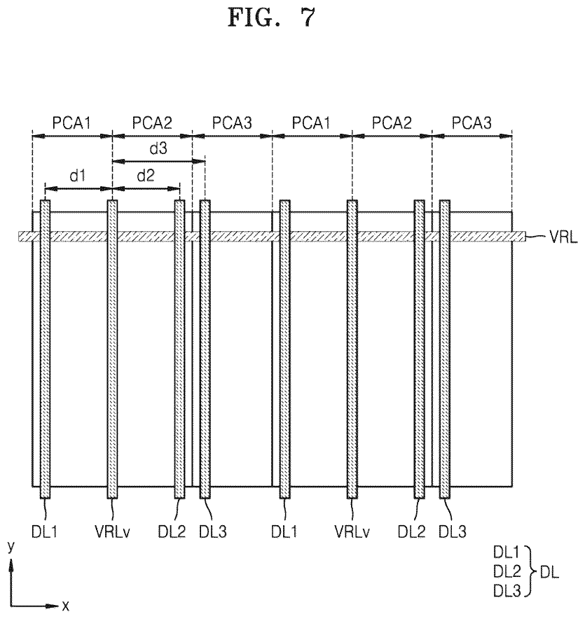

In an embodiment, the display panel 110 may further include a vertical reference voltage line VRLv (see FIG. 7) connected to the reference voltage line VRL and extending in the second direction (y direction). The vertical reference voltage line VRLv may be arranged at a certain interval from the data line DL. For example, as illustrated in FIG. 7, the vertical reference voltage line VRLv may be arranged on the boundary between the first circuit area PCA1 and the second circuit area PCA2 where the data line DL is not arranged. The vertical reference voltage line VRLv may be arranged apart from the first data line DL1, the second data line DL2, and the third data line DL3 by certain distances d1, d2, and d3, respectively. Due to the vertical reference voltage line VRLv being arranged not on the boundary between the second circuit area PCA2 and the third circuit area PCA3 but on the boundary between the first circuit area PCA1 and the second circuit area PCA2, the vertical reference voltage line VRLv and the data line DL may be spaced apart from each other by a certain distance, thereby reducing a distortion of the reference voltage VREF due to the data signal DATA.

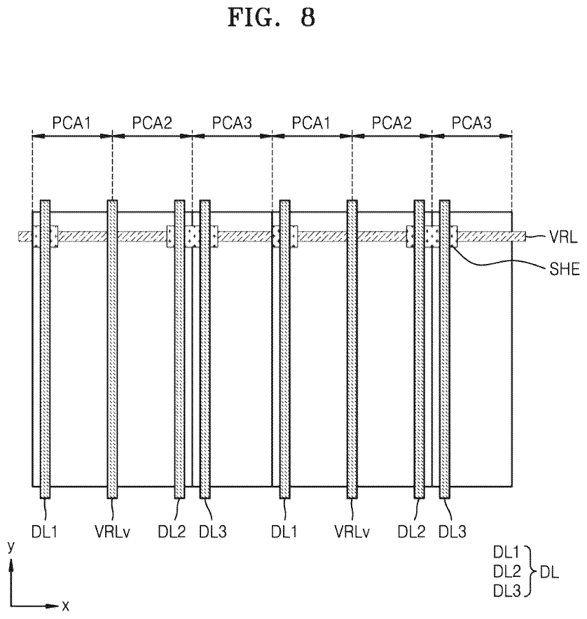

In an embodiment, as illustrated in FIG. 8, a shield portion SHE may be provided between the data line DL and the reference voltage line VRL in an area in which the data line DL and the reference voltage line VRL overlap each other, and the vertical reference voltage line VRLv may be arranged on the boundary between the first circuit area PCA1 and the second circuit area PCA2.

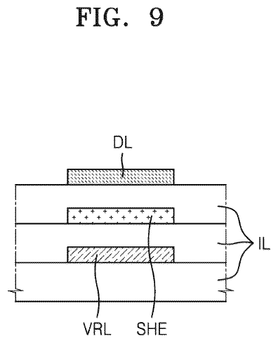

As illustrated in FIG. 9, the data line DL and the reference voltage line VRL may be arranged with at least one insulating layer IL therebetween, and the shield portion SHE may shield the reference voltage line VRL from the data line DL. In an embodiment, the shield portion SHE may be a portion of a voltage line that is connected to a pixel circuit to transmit a constant voltage to the pixel circuit.

In the embodiments illustrated in FIGS. 6 to 9, because the shield portion SHE is provided in an area in which the data line DL and the reference voltage line VRL overlap each other and/or the data line DL and the vertical reference voltage line VRLv are arranged apart from each other, a coupling distortion of the reference voltage VREF due to the data signal DATA may be minimized as illustrated in FIG. 10. For example, when the data signal DATA is written into the pixel of area A, a coupling distortion of the reference voltage VREF due to the data signal DATA may be minimized in area A and area B and thus the pixel of area B may not be affected by the distortion of the reference voltage VREF in the second period CAP′. In the display apparatus according to embodiments, the occurrence of a multi-line horizontal cross-talk in the display area DA may be minimized by reducing the distortion of the reference voltage VREF due to the data signal DATA.

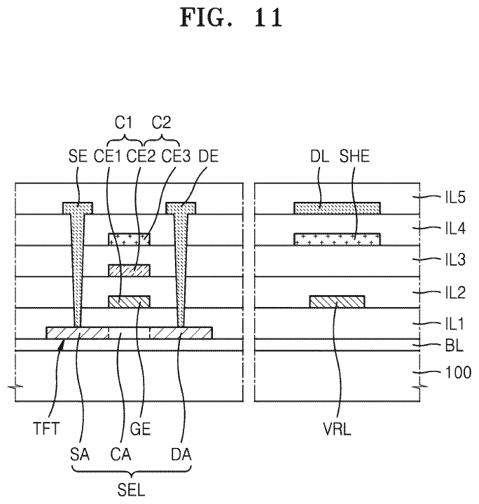

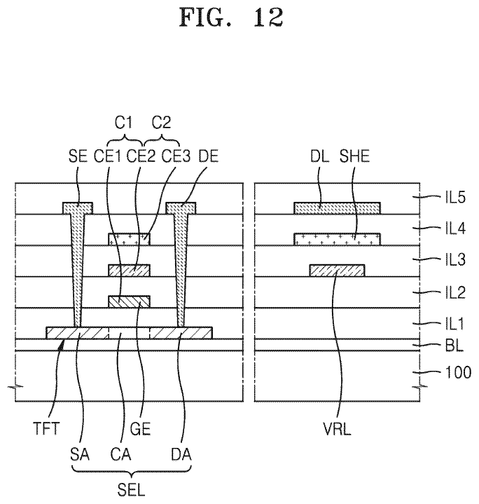

FIGS. 11 and 12 are diagrams illustrating the relationship between a data line and a reference voltage line according to an embodiment.

Referring to FIGS. 11 and 12, a thin film transistor TFT may be arranged on a substrate 100. The thin film transistor TFT illustrated in FIGS. 11 and 12 may at least correspond to at least one of the first transistor T1 to the seventh transistor T7 illustrated in FIG. 3. At least one capacitor may be arranged overlapping the thin film transistor TFT.

The thin film transistor TFT may include a semiconductor layer SEL, and a gate electrode GE, a source electrode SE, and a drain electrode DE that are arranged over the semiconductor layer SEL and insulated from the semiconductor layer SEL. The semiconductor layer SEL may include a channel area CA, a source area SA, and a drain area DA. The source electrode SE and the drain electrode DE may be electrically connected to the source area SA and the drain area DA of the semiconductor layer SEL, respectively.

The capacitor may include a first capacitor C1 and a second capacitor C2. The first capacitor C1 may include a first electrode CE1 and a second electrode CE2. The second capacitor C2 may include the second electrode CE2 and a third electrode CE3. The first electrode CE1 may be a portion of the gate electrode GE of the thin film transistor TFT.

A buffer layer BL may be arranged on the substrate 100, and a first insulating layer IL1 may be arranged between the semiconductor layer SEL and the gate electrode GE. A second insulating layer IL2, a third insulating layer IL3, and a fourth insulating layer IL4 may be arranged between the gate electrode GE and the source electrode SE and between the gate electrode GE and the drain electrode DE. The source electrode SE and the drain electrode DE may be arranged on the fourth insulating layer IL4. A fifth insulating layer IL5 may be arranged on the source electrode SE and the drain electrode DE. The second insulating layer IL2 may be arranged between the first electrode CE1 and the second electrode CE2, and the third insulating layer IL3 may be arranged between the second electrode CE2 and the third electrode CE3.

In an embodiment, as illustrated in FIG. 11, the reference voltage line VRL may be arranged on the same layer as the gate electrode GE and the first electrode CE1 of the capacitor. In an embodiment, as illustrated in FIG. 12, the reference voltage line VRL may be arranged on the same layer as the second electrode CE2 of the capacitor. The data line DL may overlap the shield portion SHE and the reference voltage line VRL and may be arranged over the fourth insulating layer IL4. The shield portion SHE may overlap the reference voltage line VRL and may be arranged between the reference voltage line VRL and the data line DL.

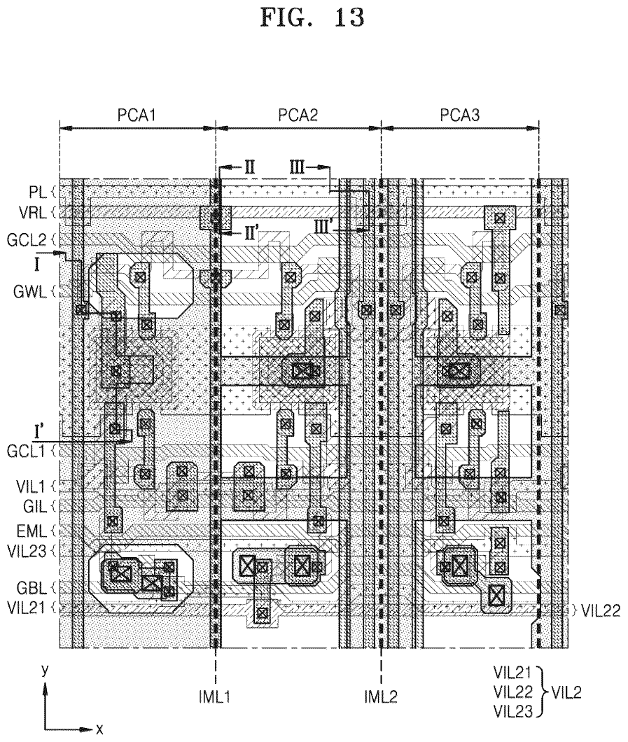

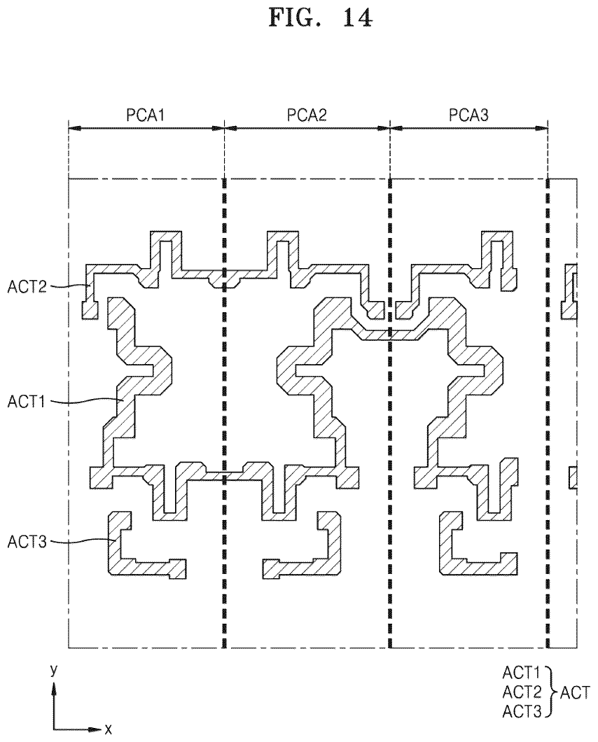

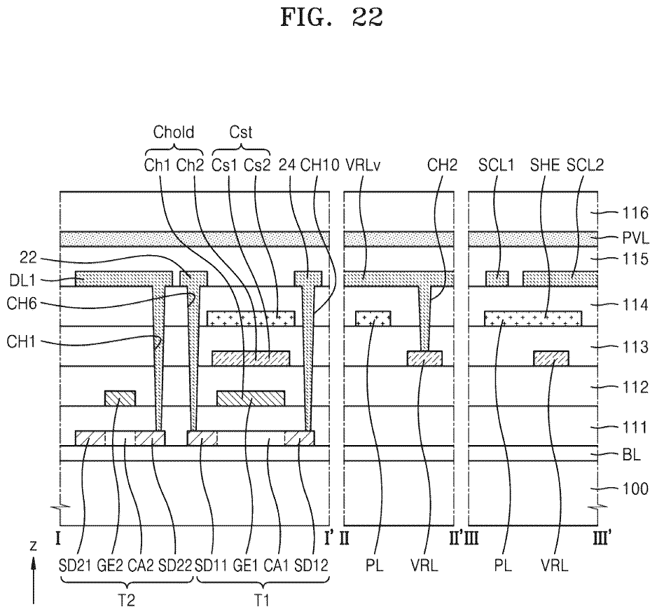

FIG. 13 is a diagram schematically illustrating circuit elements of the pixel of FIG. 3. FIGS. 14 to 21 are diagrams schematically illustrating circuit elements of the pixel of FIG. 3 on a layer-by-layer basis. FIG. 22 is a cross-sectional view of the pixel taken along lines I-I′, II-II′, and III-III′ of FIG. 13.

The same elements may be arranged in each layer of the first circuit area PCA1, the second circuit area PCA2, and the third circuit area PCA3. Hereinafter, for convenience of illustration and description, reference numerals will be assigned to the elements of the pixel circuit PC arranged in the first circuit area PCA1, and the first circuit area PCA1 will be mainly described, which may be equally applied to the same elements of the second circuit area PCA2 and the third circuit area PCA3.

Referring to FIG. 13, in an embodiment, the second initialization voltage line VIL2 may include a second-1 initialization voltage line VIL21, a second-2 initialization voltage line VIL22, and a second-3 initialization voltage line VIL23. The second-1 initialization voltage line VIL21 may be connected to a pixel circuit of the first circuit area PCA1, the second-2 initialization voltage line VIL22 may be connected to a pixel circuit of the second circuit area PCA2, and the second-3 initialization voltage line VIL23 may be connected to a pixel circuit of the third circuit area PCA3. At least one of the second initialization voltage VAINT supplied to the second-1 initialization voltage line VIL21, the second initialization voltage VAINT supplied to the second-2 initialization voltage line VIL22, and the second initialization voltage VAINT supplied to the second-3 initialization voltage line VIL23 may be different from each other. By setting the second initialization voltage differently for each pixel, it may be possible to improve the issue of low-gradation luminance change and color change due to the material influence of the organic light emitting diode OLED.

Hereinafter, descriptions will be given with reference to FIGS. 14 to 21 together. Hereinafter, a connection electrode may be an electrode for transmitting an electrical signal by connecting conductive lines and electrodes (conductive patterns) arranged in different layers.

A buffer layer BL may be arranged over a substrate 100, and a semiconductor layer ACT may be arranged over the buffer layer BL as illustrated in FIG. 14. The semiconductor layer ACT may include a first semiconductor layer ACT1, a second semiconductor layer ACT2, and a third semiconductor layer ACT3. The semiconductor layer ACT may include a source area, a drain area, and a channel area between the source area and the drain area in each of the first to seventh transistors T1 to T7. The source area or the drain area may be interpreted as a source electrode or a drain electrode of a transistor in some cases.

The first semiconductor layer ACT1 of the first circuit area PCA1, the first semiconductor layer ACT1 of the second circuit area PCA2, and the first semiconductor layer ACT1 of the third circuit area PCA3 may be connected. In an embodiment, the first semiconductor layer ACT1 of the first circuit area PCA1, the first semiconductor layer ACT1 of the second circuit area PCA2, and the first semiconductor layer ACT1 of the third circuit area PCA3 may be integrally formed as one body. The second semiconductor layer ACT2 of the first circuit area PCA1 and the second semiconductor layer ACT2 of the second circuit area PCA2 may be connected. In an embodiment, the second semiconductor layer ACT2 of the first circuit area PCA1 and the second semiconductor layer ACT2 of the second circuit area PCA2 may be integrally formed as one body. The third semiconductor layer ACT3 may be provided in each of the first circuit area PCA1, the second circuit area PCA2, and the third circuit area PCA3.

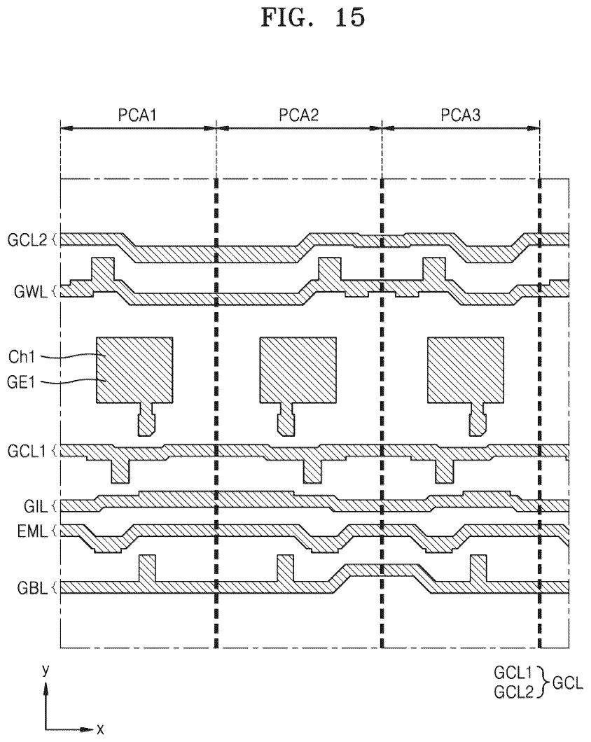

A first insulating layer 111 may be arranged over the buffer layer BL, and the first insulating layer 111 may cover the semiconductor layer ACT. A first conductive layer may be arranged over the first insulating layer 111. As illustrated in FIG. 15, the first conductive layer may include a first gate line GWL, a second gate line GIL, a third gate line GCL, a fourth gate line EML, and a fifth gate line GBL. The third gate line GCL may include a third-1 gate line GCL1 and a third-2 gate line GCL2.

The first gate line GWL, the second gate line GIL, the third gate line GCL, the fourth gate line EML, and the fifth gate line GBL may extend in the first direction and may be arranged across the first circuit area PCA1, the second circuit area PCA2, and the third circuit area PCA3.

The first conductive layer may include gate electrodes GE1 to GE7 of the first to seventh transistors T1 to T7. The gate electrode GE1 of the first transistor T1 may be provided as an island type. The gate electrode GE1 of the first transistor T1 may include a lower electrode Ch1 of the second capacitor Chold. The gate electrode GE1 of the first transistor T1 may overlap the first semiconductor layer ACT1. The gate electrode GE2 of the second transistor T2 may be a portion of the first gate line GWL overlapping the second semiconductor layer ACT2. The gate electrode GE3 of the third transistor T3 may be a portion of the third-1 gate line GCL1 overlapping the first semiconductor layer ACT1. The gate electrode GE4 of the fourth transistor T4 may be a portion of the second gate line GIL overlapping the first semiconductor layer ACT1. The gate electrode GE5 of the fifth transistor T5 may be a portion of the third-2 gate line GCL2 overlapping the second semiconductor layer ACT2. The gate electrode GE6 of the sixth transistor T6 may be a portion of the fourth gate line EML overlapping the third semiconductor layer ACT3. The gate electrode GE7 of the seventh transistor T7 may be a portion of the fifth gate line GBL overlapping the third semiconductor layer ACT3.

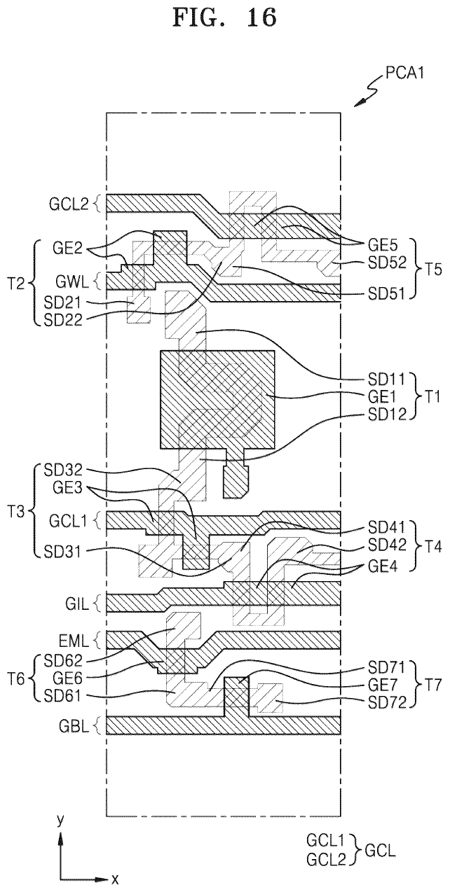

FIG. 16 is a diagram illustrating transistors of the first circuit area PCA1.

Referring to FIG. 16, each of the first to seventh transistors T1 to T7 may include a semiconductor layer and a gate electrode on the semiconductor layer. One end of the semiconductor layer of each of the first to seventh transistors T1 to T7 may be a source area or a drain area, and the other end thereof may be a drain area or a source area. Hereinafter, one end of the semiconductor layer of each of the first to seventh transistors T1 to T7 will be referred to as a first source-drain area, and the other end thereof will be referred to as a second source-drain area. The semiconductor layer may include a channel area between the first source-drain area and the second source-drain area, and the gate electrode may overlap the channel area.

In an embodiment, each of the second transistor T2, the third transistor T3, the fourth transistor T4, and the fifth transistor T5 may be a double-gate transistor including two gate electrodes located adjacent to each other on the same layer. The second transistor T2, the third transistor T3, the fourth transistor T4, and the fifth transistor T5 may have a structure in which two sub-transistors are connected in series.

The first semiconductor layer ACT1 may include a semiconductor layer of the first transistor T1, a semiconductor layer of the third transistor T3, and a semiconductor layer of the fourth transistor T4. The second semiconductor layer ACT2 may include a semiconductor layer of the second transistor T2 and a semiconductor layer of the fifth transistor T5. The third semiconductor layer ACT3 may include a semiconductor layer of the sixth transistor T6 and a semiconductor layer of the seventh transistor T7.

The semiconductor layer of the first transistor T1 may include a first source-drain area SD11, a second source-drain area SD12, and a channel area CA1 (see FIG. 22) between the first source-drain area SD11 and the second source-drain area SD12. The gate electrode GE1 of the first transistor T1 may overlap the channel area CA1 of the semiconductor layer of the first transistor T1. The channel area CA1 of the semiconductor layer of the first transistor T1 may have a curve.

The semiconductor layer of the second transistor T2 may include a first source-drain area SD21, a second source-drain area SD22, and a channel area CA2 (see FIG. 22) between the first source-drain area SD21 and the second source-drain area SD22. The gate electrode GE2 of the second transistor T2 may include a first gate electrode formed by a portion of the first gate line GWL in the first direction and a second gate electrode formed by a protrusion portion in the second direction (y direction). The channel area CA2 of the second transistor T2 may include a first channel area overlapping the first gate electrode and a second channel area overlapping the second gate electrode.

The semiconductor layer of the third transistor T3 may include a first source-drain area SD31, a second source-drain area SD32, and a channel area between the first source-drain area SD31 and the second source-drain area SD32. The gate electrode GE3 of the third transistor T3 may include a first gate electrode formed by a portion of the third-1 gate line GCL1 in the first direction and a second gate electrode formed by a protrusion portion in the second direction. The channel area of the third transistor T3 may include a first channel area overlapping the first gate electrode and a second channel area overlapping the second gate electrode.

The semiconductor layer of the fourth transistor T4 may include a first source-drain area SD41, a second source-drain area SD42, and a channel area between the first source-drain area SD41 and the second source-drain area SD42. The gate electrode GE4 of the fourth transistor T4 may include a first gate electrode and a second gate electrode formed by a portion of the second gate line GIL in the first direction. The channel area of the fourth transistor T4 may include a first channel area overlapping the first gate electrode and a second channel area overlapping the second gate electrode.

The semiconductor layer of the fifth transistor T5 may include a first source-drain area SD51, a second source-drain area SD52, and a channel area between the first source-drain area SD51 and the second source-drain area SD52. The gate electrode GE5 of the fifth transistor T5 may include a first gate electrode and a second gate electrode formed by a portion of the third-2 gate line GCL2 in the first direction. The channel area of the fifth transistor T5 may include a first channel area overlapping the first gate electrode and a second channel area overlapping the second gate electrode. In an embodiment, the pixel circuit arranged in the first circuit area PCA1 and the pixel circuit arranged in the second circuit area PCA2 may share the second source-drain area SD52 of the fifth transistor T5.

The semiconductor layer of the sixth transistor T6 may include a first source-drain area SD61, a second source-drain area SD62, and a channel area between the first source-drain area SD61 and the second source-drain area SD62. The gate electrode GE6 of the sixth transistor T6 may overlap the channel area of the semiconductor layer of the sixth transistor T6.

The semiconductor layer of the seventh transistor T7 may include a first source-drain area SD71, a second source-drain area SD72, and a channel area between the first source-drain area SD71 and the second source-drain area SD72. The gate electrode GE7 of the seventh transistor T7 may overlap the channel area of the semiconductor layer of the seventh transistor T7.

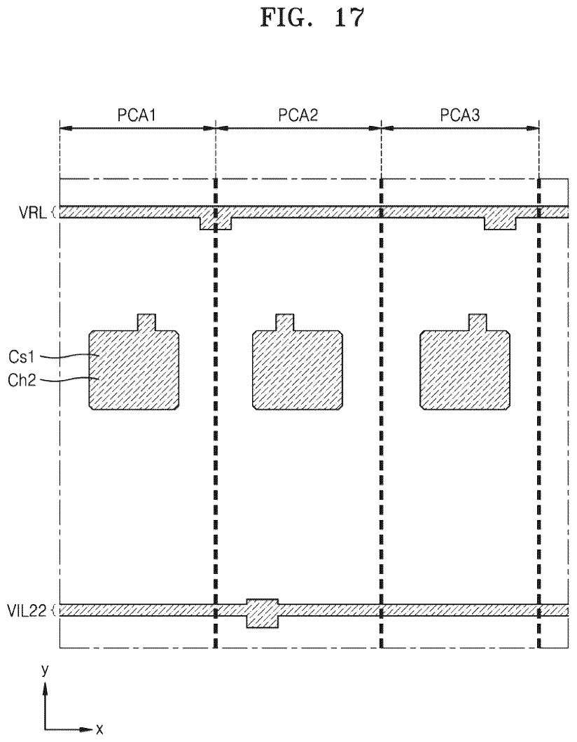

A second insulating layer 112 may be arranged over the first insulating layer 111, and the second insulating layer 112 may cover the first conductive layer. A second conductive layer may be arranged over the second insulating layer 112. As illustrated in FIG. 17, the second conductive layer may include a reference voltage line VRL, a second-2 initialization voltage line VIL22, and an upper electrode Ch2 of the second capacitor Chold.

The reference voltage line VRL and the second-2 initialization voltage line VIL22 may extend in the first direction and may be arranged across the first circuit area PCA1, the second circuit area PCA2, and the third circuit area PCA3.

The upper electrode Ch2 of the second capacitor Chold may overlap the lower electrode Ch1 of the second capacitor Chold. The upper electrode Ch2 of the second capacitor Chold may include a lower electrode Cs1 of the first capacitor Cst.

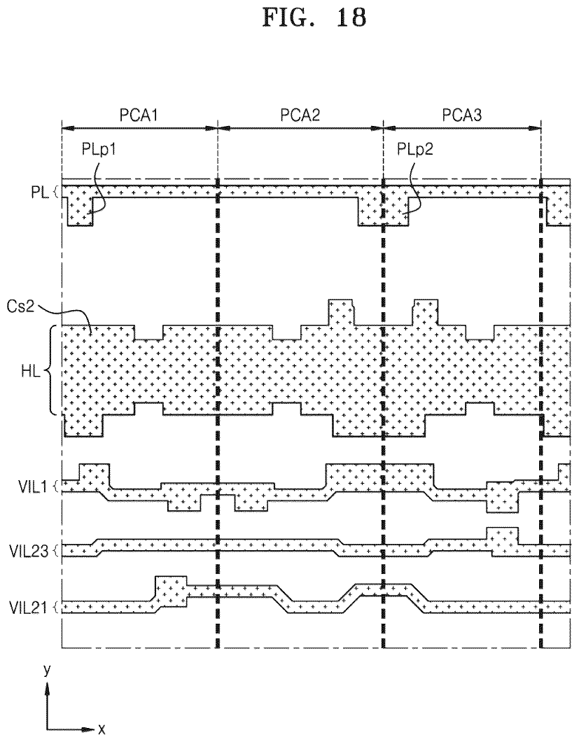

A third insulating layer 113 may be arranged over the second insulating layer 112, and the third insulating layer 113 may cover the second conductive layer. A third conductive layer may be arranged over the third insulating layer 113. As illustrated in FIG. 18, the third conductive layer may include a driving voltage line PL, a horizontal electrode layer HL, a first initialization voltage line VIL1, a second-1 initialization voltage line VIL21, and a second-3 initialization voltage line VIL23.

The driving voltage line PL, the horizontal electrode layer HL, the first initialization voltage line VIL1, the second-1 initialization voltage line VIL21, and the second-3 initialization voltage line VIL23 may extend in the first direction and may be arranged across the first circuit area PCA1, the second circuit area PCA2, and the third circuit area PCA3.

The driving voltage line PL may include a portion (first protrusion portion) PLp1 protruding in the second direction in the first circuit area PCA1 and a portion (second protrusion portion) PLp2 protruding in the second direction in the second circuit area PCA2 and the third circuit area PCA3.

The horizontal electrode layer HL may overlap the first transistor T1 and the second capacitor Chold. The horizontal electrode layer HL may include an upper electrode Cs2 of the first capacitor Cst. The upper electrode Cs2 of the first capacitor Cst arranged in each of the first circuit area PCA1, the second circuit area PCA2, and the third circuit area PCA3 may be connected. For example, the upper electrode Cs2 of the first capacitor Cst arranged in each of the first circuit area PCA1, the second circuit area PCA2, and the third circuit area PCA3 may be integrally formed as one boby, and thus, the horizontal electrode layer HL may be an electrode common to the pixel circuits of the first circuit area PCA1, the second circuit area PCA2, and the third circuit area PCA3.

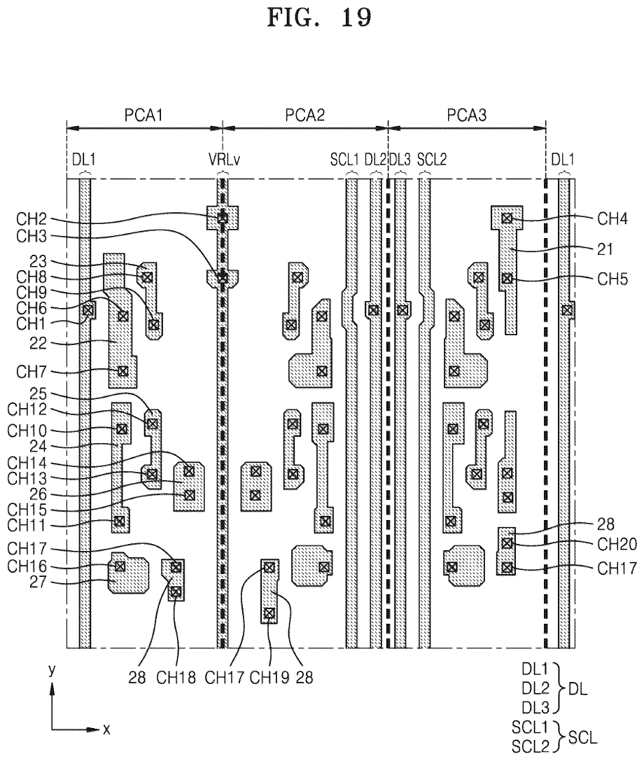

A fourth insulating layer 114 may be arranged over the third insulating layer 113, and the fourth insulating layer 114 may cover the third conductive layer. A fourth conductive layer may be arranged over the fourth insulating layer 114. As illustrated in FIG. 19, the fourth conductive layer may include a data line DL, a vertical reference voltage line VRLv, a shared voltage line SCL, and connection electrodes 21, 22, 23, 24, 25, 26, 27, and 28. The connection electrode 21 may be arranged only in the third circuit area PCA3, and the connection electrodes 22, 23, 24, 25, 26, 27, and 28 may be arranged in each of the first circuit area PCA1, the second circuit area PCA2, and the third circuit area PCA3. The shared voltage line SCL may be omitted.

The data line DL, the vertical reference voltage line VRLv, and the shared voltage line SCL may extend in the second direction (y direction).

The data line DL may include a first data line DL1 connected to a pixel circuit of the first circuit area PCA1, a second data line DL2 connected to a pixel circuit of the second circuit area PCA2, and a third data line DL3 connected to a pixel circuit of the third circuit area PCA3. Each of the first data line DL1, the second data line DL2, and the third data line DL3 may be arranged in the corresponding circuit area. The first data line DL1 connected to the pixel circuit of the first pixel may be arranged on one side (e.g., the left side) of the first circuit area PCA1, the second data line DL2 connected to the pixel circuit of the second pixel may be arranged on one side (e.g., the right side) of the second circuit area PCA2, and the third data line DL3 connected to the pixel circuit of the third pixel may be arranged on one side (e.g., the left side) of the third circuit area PCA3.

Each of the first data line DL1, the second data line DL2, and the third data line DL3 may be connected to a second source-drain area SD22 of the second transistor T2 by contacting the second source-drain area SD22 of the second transistor T2 arranged in the corresponding circuit area through a contact hole CH1 in the first insulating layer 111, the second insulating layer 112, the third insulating layer 113, and the fourth insulating layer 114. Each of the first data line DL1, the second data line DL2, and the third data line DL3 may not overlap the first transistor T1, the first capacitor Cst, and the second capacitor Chold arranged in the corresponding circuit area. The second data line DL2 and the third data line DL3 may be arranged apart from each other on either side of the boundary between the second circuit area PCA2 and the third circuit area PCA3.

The vertical reference voltage line VRLv may be arranged on the boundary between the first circuit area PCA1 and the second circuit area PCA2. The vertical reference voltage line VRLv may be connected to the reference voltage line VRL by contacting the reference voltage line VRL through a contact hole CH2 in the third insulating layer 113 and the fourth insulating layer 114. The vertical reference voltage line VRLv may be connected to a second source-drain area SD52 by contacting the second source-drain area SD52 shared by the fifth transistors T5 arranged in the first circuit area PCA1 and the second circuit area PCA2 through a contact hole CH3 in the first insulating layer 111, the second insulating layer 112, the third insulating layer 113, and the fourth insulating layer 114.

The shared voltage line SCL may include a first shared voltage line SCL1 and a second shared voltage line SCL2. The first shared voltage line SCL1 and the second shared voltage line SCL2 may be arranged apart from each other on either side of the boundary between the second circuit area PCA2 and the third circuit area PCA3. The first shared voltage line SCL1 and the second shared voltage line SCL2 may be arranged to have the second data line DL2 and the third data line DL3 therebetween. In an embodiment, the first shared voltage line SCL1 and the second shared voltage line SCL2 may be a vertical voltage line (vertical conductive line) connected to one of the driving voltage line PL, the first initialization voltage line VIL1, the second-1 initialization voltage line VIL21, the second-2 initialization voltage line VIL22, the second-3 initialization voltage line VIL23, and a common voltage line. The first shared voltage line SCL1 and the second shared voltage line SCL2 may be arranged at certain intervals in the x direction according to a certain rule.

By the shared voltage line SCL, at least one of the driving voltage line PL, the first initialization voltage line VIL1, the second-1 initialization voltage line VIL21, the second-2 initialization voltage line VIL22, and the second-3 initialization voltage line VIL23 may have a mesh structure in the display area DA. In an embodiment, the driving voltage line PL, the first initialization voltage line VIL1, the second-1 initialization voltage line VIL21, the second-2 initialization voltage line VIL22, the second-3 initialization voltage line VIL23, and/or the shared voltage line SCL may be connected to a voltage supply line arranged in the peripheral area PA. In an embodiment, the common voltage line may be connected to an opposite electrode in the display area DA and/or a common voltage supply line in the peripheral area PA to transmit the second driving voltage ELVSS.

The connection electrode 21 (see FIG. 19) may be arranged in the third circuit area PCA3 and may be connected to the reference voltage line VRL by contacting the reference voltage line VRL through a contact hole CH4 in the third insulating layer 113 and the fourth insulating layer 114. The connection electrode 21 may be connected to a second source-drain area SD52 by contacting the second source-drain area SD52 of the fifth transistor T5 arranged in the third circuit area PCA3 through a contact hole CH5 in the first insulating layer 111, the second insulating layer 112, the third insulating layer 113, and the fourth insulating layer 114.

The connection electrode 22 may be connected to the first source-drain area SD11 by contacting the first source-drain area SD11 of the first transistor T1 through a contact hole CH6 that extends through the first insulating layer 111, the second insulating layer 112, the third insulating layer 113, and the fourth insulating layer 114. The connection electrode 22 may be connected to the horizontal electrode layer HL by contacting the horizontal electrode layer HL through a contact hole CH7 extending through the fourth insulating layer 114.

The connection electrode 23 may be connected to the second source-drain area SD22 and the first source-drain area SD51 by contacting the second source-drain area SD22 of the second transistor T2 and the first source-drain area SD51 of the fifth transistor T5 through a contact hole CH8 in the first insulating layer 111, the second insulating layer 112, the third insulating layer 113, and the fourth insulating layer 114. The connection electrode 23 may be connected to the lower electrode Cs1 and the upper electrode Ch2 by contacting the lower electrode Cs1 of the first capacitor Cst and the upper electrode Ch2 of the second capacitor Chold through a contact hole CH9 in the third insulating layer 113 and the fourth insulating layer 114. The connection electrode 23 may correspond to the second node N2.

The connection electrode 24 may be connected to the first source-drain area SD11 by contacting the first source-drain area SD11 of the first transistor T1 through a contact hole CH10 in the first insulating layer 111, the second insulating layer 112, the third insulating layer 113, and the fourth insulating layer 114. The connection electrode 24 may be connected to the second source-drain area SD32 by contacting the second source-drain area SD32 of the third transistor T3 through a contact hole CH11 in the first insulating layer 111, the second insulating layer 112, the third insulating layer 113, and the fourth insulating layer 114.

The connection electrode 25 may be connected to the gate electrode GE1 and the lower electrode Ch1 by contacting the gate electrode GE1 of the first transistor T1 and the lower electrode Ch1 of the second capacitor Chold through a contact hole CH12 in the second insulating layer 112, the third insulating layer 113, and the fourth insulating layer 114. The connection electrode 25 may be connected to the first source-drain area SD41 by contacting the first source-drain area SD41 of the fourth transistor T4 through a contact hole CH13 in the first insulating layer 111, the second insulating layer 112, the third insulating layer 113, and the fourth insulating layer 114. The connection electrode 26 may be connected to the second source-drain area SD42 by contacting the second source-drain area SD42 of the fourth transistor T4 through a contact hole CH14 in the first insulating layer 111, the second insulating layer 112, the third insulating layer 113, and the fourth insulating layer 114. The connection electrode 26 may be connected to the first initialization voltage line VIL1 by contacting the first initialization voltage line VIL1 through a contact hole CH15 in the fourth insulating layer 114.

The connection electrode 27 may be connected to the first source-drain area SD61 and the first source-drain area SD71 by contacting the first source-drain area SD61 of the sixth transistor T6 and the first source-drain area SD71 of the seventh transistor T7 through a contact hole CH16 in the first insulating layer 111, the second insulating layer 112, the third insulating layer 113, and the fourth insulating layer 114.

The connection electrode 28 may be connected to the second source-drain area SD72 by contacting the second source-drain area SD72 of the seventh transistor T7 through a contact hole CH17 in the first insulating layer 111, the second insulating layer 112, the third insulating layer 113, and the fourth insulating layer 114. In the first circuit area PCA1, the connection electrode 28 may be connected to the second-1 initialization voltage line VIL21 by contacting the second-1 initialization voltage line VIL21 through a contact hole CH18 in the fourth insulating layer 114. In the second circuit area PCA2, the connection electrode 28 may be connected to the second-2 initialization voltage line VIL22 by contacting the second-2 initialization voltage line VIL22 through a contact hole CH19 in the third insulating layer 113 and the fourth insulating layer 114. In the third circuit area PCA3, the connection electrode 28 may be connected to the second-3 initialization voltage line VIL23 by contacting the second-3 initialization voltage line VIL23 through a contact hole CH20 in the fourth insulating layer 114.

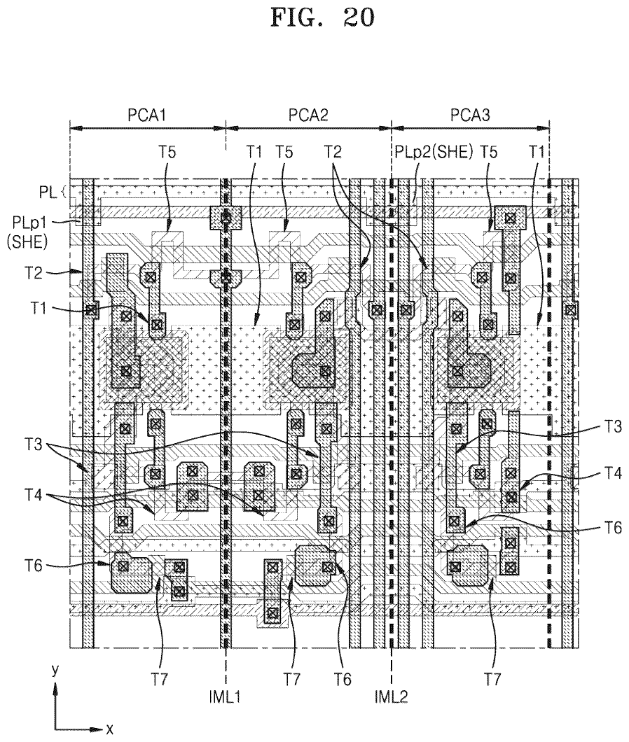

Referring to FIG. 20, the pixel circuit of the first circuit area PCA1 and the pixel circuit of the second circuit area PCA2 may be symmetrical with respect to the boundary between the first circuit area PCA1 and the second circuit area PCA2. The pixel circuit of the second circuit area PCA2 and the pixel circuit of the third circuit area PCA3 may be symmetrical with respect to the boundary between the second circuit area PCA2 and the third circuit area PCA3. For example, the arrangement of the circuit elements constituting the pixel circuit of the first circuit area PCA1 and the pixel circuit of the second circuit area PCA2 may be line symmetrical (bilaterally symmetrical) with respect to an imaginary line IML1 along the boundary between the first circuit area PCA1 and the second circuit area PCA2. The arrangement of the circuit elements constituting the pixel circuit of the second circuit area PCA2 and the pixel circuit of the third circuit area PCA3 may be line symmetrical (bilaterally symmetrical) with respect to an imaginary line IML2 along the boundary between the second circuit area PCA2 and the third circuit area PCA3.

In a plan view, the first data line DL1 and the second data line DL2 may be arranged parallel to and apart from each other with the first transistor T1 of the pixel circuit arranged in the first circuit area PCA1 and the first transistor T1 of the pixel circuit arranged in the second circuit area PCA2 therebetween. In a plan view, the second data line DL2 and the third data line DL3 may be arranged parallel to and apart from each other between the first transistor T1 of the pixel circuit arranged in the second circuit area PCA2 and the first transistor T1 of the pixel circuit arranged in the third circuit area PCA3.

In a plan view, the first transistor T1 of the pixel circuit arranged in the first circuit area PCA1 may be arranged between the first data line DL1 and the vertical reference voltage line VRLv, and the first transistor T1 of the pixel circuit arranged in the second circuit area PCA2 may be arranged between the vertical reference voltage line VRLv and the second data line DL2.

In a plan view, at least one shared voltage line SCL extending in the second direction may be arranged close to the boundary between the second circuit area PCA2 and the third circuit area PCA3. The shared voltage line SCL may be arranged next to at least one of the second data line DL2 and the third data line DL3, on the side that is not occupied by the other data line. The shared voltage line SCL may be connected to at least one of the first-direction constant voltage lines connected to the pixel circuit arranged in the first circuit area PCA1, the pixel circuit arranged in the second circuit area PCA2, and the pixel circuit arranged in the third circuit area PCA3.

Each of the first protrusion portion PLp1 and the second protrusion portion PLp2 of the driving voltage line PL may be the shield portion SHE. The first protrusion portion PLp1 of the driving voltage line PL may be a first shield portion located in a layer between the reference voltage line VRL and the first data line DL1 and may overlap the first data line DL1 in an area in which the reference voltage line VRL and the first data line DL1 overlap each other. The second protrusion portion PLp2 of the driving voltage line PL may be a second shield portion located in a layer between the reference voltage line VRL and the second data line DL2 and the third data line DL3 and may overlap the second data line DL2 and the third data line DL3 in an area in which the reference voltage line VRL and the second data line DL2 and the third data line DL3 overlap each other.

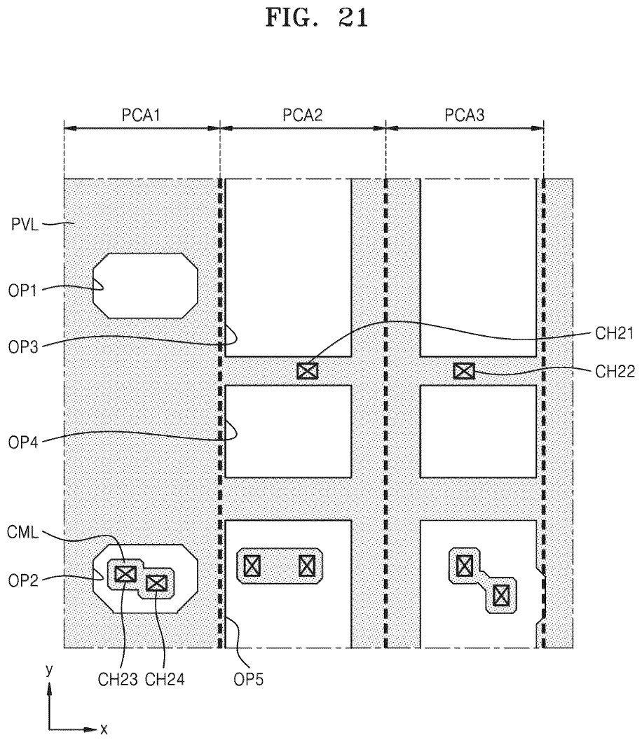

A fifth insulating layer 115 may be arranged on the fourth insulating layer 114, and the fifth insulating layer 115 may cover the fourth conductive layer. A fifth conductive layer may be arranged on the fifth insulating layer 115. As illustrated in FIG. 21, the fifth conductive layer may include a driving voltage electrode layer PVL and connection electrodes CML.

The driving voltage electrode layer PVL may be connected to the connection electrode 22 by contacting the connection electrode 22 arranged in the second circuit area PCA2 through a contact hole CH21 in the fifth insulating layer 115. The driving voltage electrode layer PVL may be connected to the connection electrode 22 arranged in the third circuit area PCA3 through a contact hole CH22 in the fifth insulating layer 115. The driving voltage electrode layer PVL may be connected to the horizontal electrode layer HL through the connection electrode 22. The first driving voltage ELVDD may be transmitted to the display area DA through the driving voltage line PL, the horizontal electrode layer HL, and the driving voltage electrode layer PVL.

A first opening OP1 and a second opening OP2 overlapping the first circuit area PCA1 as well as a third opening OP3, a fourth opening OP4, and a fifth opening OP5 overlapping the second circuit area PCA2 and the third circuit area PCA3 may be defined in the driving voltage electrode layer PVL. Each of the second opening OP2 and the fifth opening OP5 of the driving voltage electrode layer PVL may overlap the connection electrode CML arranged in the corresponding circuit area.

The connection electrode CML may be connected to the connection electrode 27 by contacting the connection electrode 27 through a contact hole CH23 in the fifth insulating layer 115. As illustrated in FIG. 22, a sixth insulating layer 116 may be arranged on the fifth insulating layer 115. The connection electrode CML may be connected to the display element on the sixth insulating layer 116 through a contact hole CH24 in the sixth insulating layer 116. The first capacitor Cst illustrated in FIGS. 13 to 22 may correspond to the second capacitor C2 illustrated in FIGS. 11 and 12, the second capacitor Chold illustrated in FIGS. 13 to 22 may correspond to the first capacitor C1 illustrated in FIG. 11, and first insulating layer 111 to the fifth insulating layer 115 illustrated in FIGS. 13 to 22 may correspond to the first insulating layer IL1 to the fifth insulating layer IL5 illustrated in FIGS. 11 and 12.

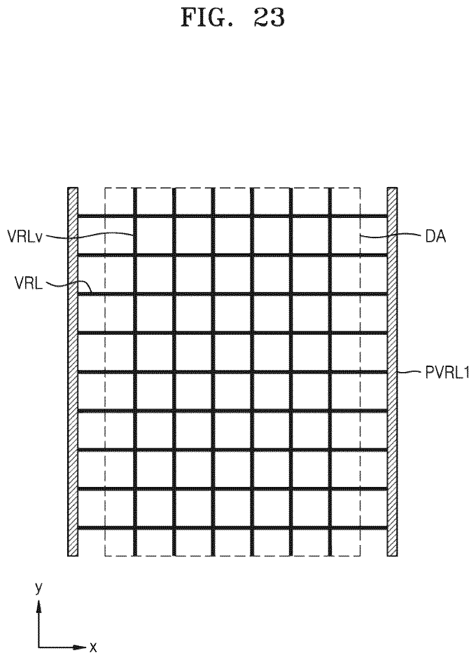

FIGS. 23 to 25 are diagrams schematically illustrating a reference voltage line according to an embodiment.

Referring to FIGS. 23 to 25, in the display area DA, the reference voltage line VRL may extend in the first direction, and the vertical reference voltage line VRLv may extend in the second direction and may be connected to the reference voltage line VRL. In an embodiment, the reference voltage line VRL and the vertical reference voltage line VRLv may be arranged in different layers and may be directly connected through a contact hole. In an embodiment, the reference voltage line VRL and the vertical reference voltage line VRLv may be respectively arranged in different layers and may be indirectly connected through a connection electrode located in a layer between the reference voltage line VRL and the vertical reference voltage line VRLv.

In the peripheral area PA, the reference voltage line VRL and/or the vertical reference voltage line VRLv may be electrically connected to a reference voltage supply line PVRL arranged in the peripheral area PA and may receive the reference voltage VREF from the reference voltage supply line PVRL. The reference voltage supply line PVRL may include a first reference voltage supply line PVRL1 connected to the reference voltage lines VRL and a second reference voltage supply line PVRL2 connected to the vertical reference voltage lines VRLv.

In an embodiment, as illustrated in FIG. 23, the first reference voltage supply line PVRL1 may be in the peripheral area PA extending in the second direction, and may be connected to one end of each of a plurality of reference voltage lines VRL extending from the display area DA. The reference voltage lines VRL and the vertical reference voltage lines VRLv arranged in the display area DA may receive the reference voltage VREF from the first reference voltage supply line PVRL1. The first reference voltage supply line PVRL1 may be arranged on the left side and/or right side of the display area DA.

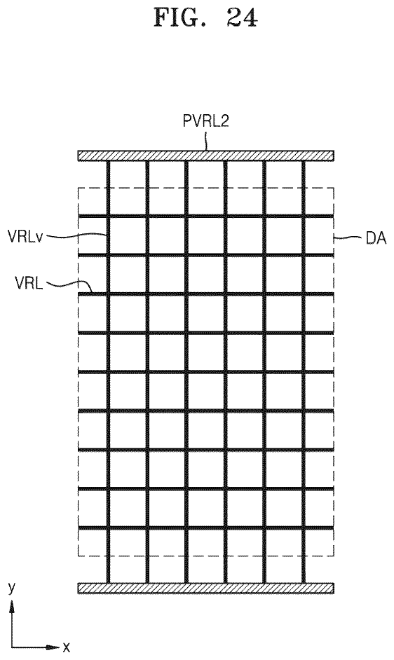

In an embodiment, as illustrated in FIG. 24, the second reference voltage supply line PVRL2 extending in the first direction may be connected to one end of each of a plurality of vertical reference voltage lines VRLv extending from the display area DA in the peripheral area PA. The reference voltage lines VRL and the vertical reference voltage lines VRLv arranged in the display area DA may receive the reference voltage VREF from the second reference voltage supply line PVRL2. The second reference voltage supply line PVRL2 may be arranged on the upper side and/or lower side of the display area DA.

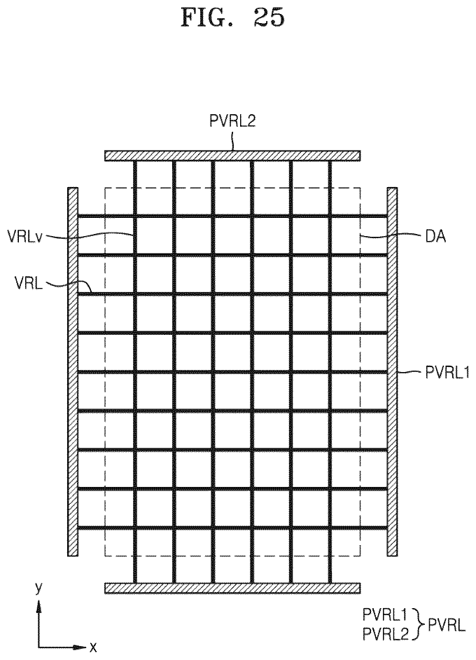

In an embodiment, as illustrated in FIG. 25, the first reference voltage supply line PVRL1 may be connected to one end of each of a plurality of reference voltage lines VRL extending from the display area DA in the peripheral area PA, and the second reference voltage supply line PVRL2 may be connected to one end of each of a plurality of vertical reference voltage lines VRLv extending from the display area DA in the peripheral area PA. The reference voltage lines VRL and the vertical reference voltage lines VRLv arranged in the display area DA may receive the reference voltage VREF from the first reference voltage supply line PVRL1 and the second reference voltage supply line PVRL2. In an embodiment, the first reference voltage supply line PVRL1 and the second reference voltage supply line PVRL2 may be arranged apart from each other as illustrated in FIG. 25. In an embodiment, the first reference voltage supply line PVRL1 and the second reference voltage supply line PVRL2 may be connected and integrally connected to each other.

As illustrated in FIG. 13, in an embodiment, the shield portion SHE that is a portion of a driving voltage line PL may be arranged between the data line DL and the reference voltage line VRL, and the vertical reference voltage line VRLv may be arranged on the boundary between the first circuit area PCA1 and the second circuit area PCA2 where the data line DL is not arranged. Accordingly, a distortion of the reference voltage VREF due to the data signal DATA may be reduced. However, the present embodiments are not limited thereto.

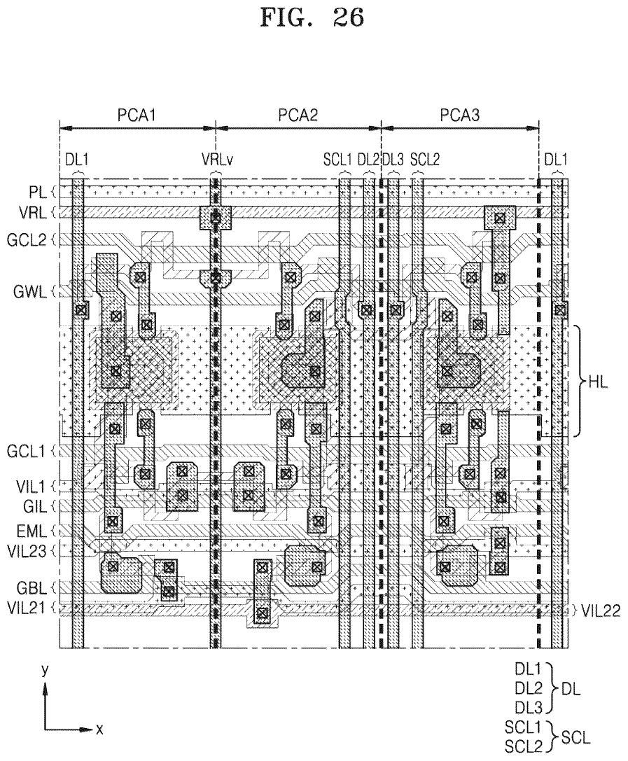

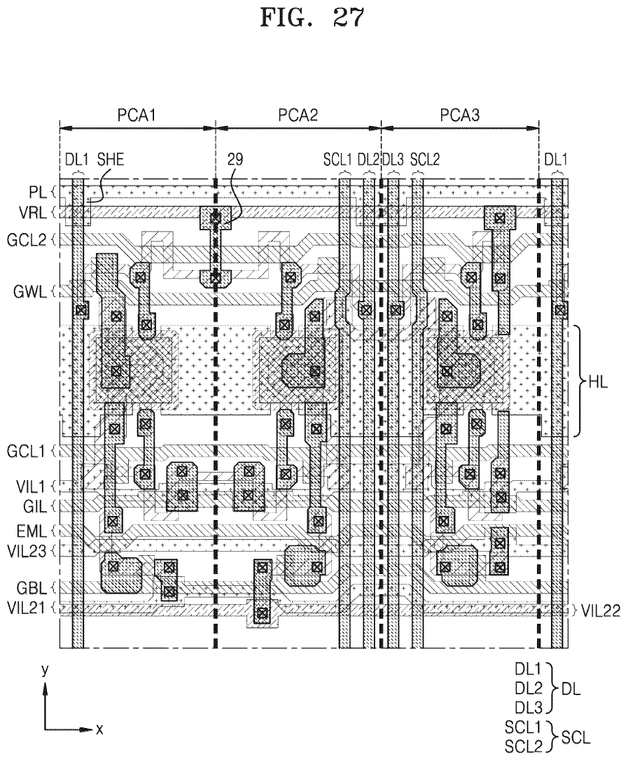

FIGS. 26 and 27 are arrangement diagrams schematically illustrating circuit elements of the pixel of FIG. 3 according to an embodiment.

As illustrated in FIG. 26, in an embodiment, without a shield portion SHE, the vertical reference voltage line VRLv may be arranged on the boundary between the first circuit area PCA1 and the second circuit area PCA2 that is a position spaced apart by a certain distance from the data line DL. Accordingly, a distortion of the reference voltage VREF due to the data signal DATA may be reduced. The first shared voltage line SCL1 and the second shared voltage line SCL2 may not be connected to the reference voltage line VRL. As illustrated in FIG. 26 and FIG. 27, in plan view, the first shared voltage line SCL1 and the second shared voltage line SCL2 are arranged such that they sandwich the second data line DL2 and the third data line DL3 between them. Each of the second data line DL2 and the third data line DL3 has the other data line to one side of it and a shared voltage line SCL1/SCL2 on the other side. A boundary between the second circuit area PCA2 and the third circuit area PCA3 extend between and parallel to the second data line DL2 and the third data line DL3.

As illustrated in FIG. 27, in an embodiment, a shield portion SHE may be arranged between the data line DL and the reference voltage line VRL. Accordingly, a distortion of the reference voltage VREF due to the data signal DATA may be reduced. At least one of the first shared voltage line SCL1 and the second shared voltage line SCL2 may be connected to the reference voltage line VRL, and the vertical reference voltage line VRLv illustrated in FIG. 19 and FIG. 26 may be omitted. At least one of the first shared voltage line SCL1 and the second shared voltage line SCL2 may function as the vertical reference voltage line VRLv. A connection electrode 29 may be arranged on the boundary between the first circuit area PCA1 and the second circuit area PCA2. The connection electrode 29 may be arranged on the same layer as the data line DL and may be connected to the reference voltage line VRL and the second source-drain area SD52 by contacting the reference voltage line VRL and the second source-drain area SD52 of the fifth transistor T5 through contact holes in insulating layers.

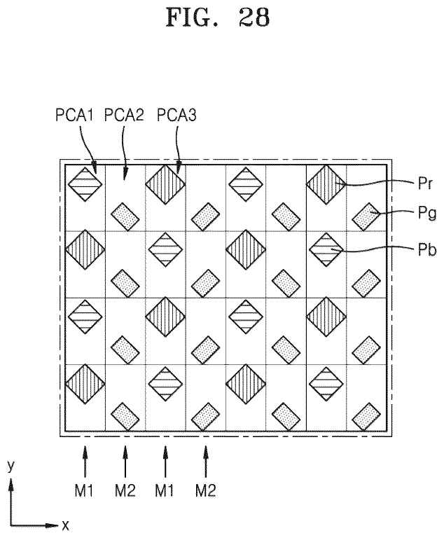

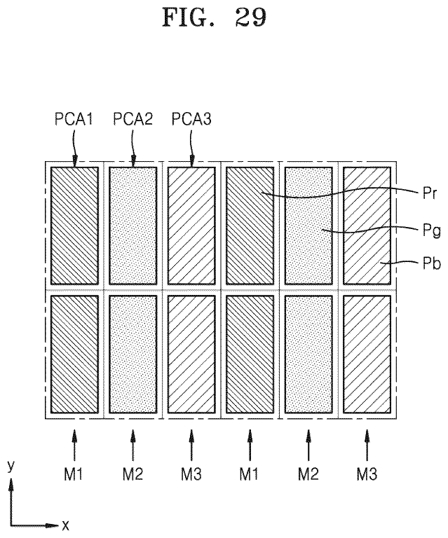

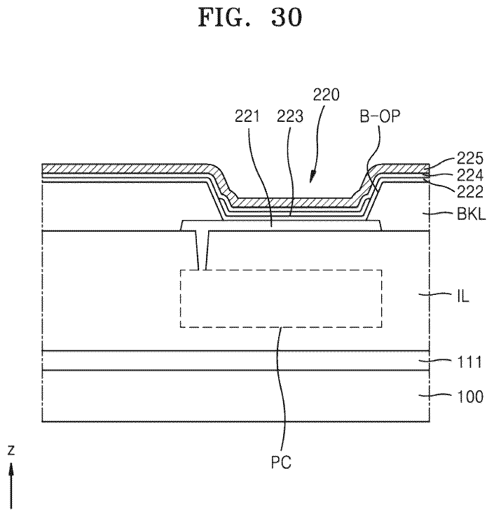

FIGS. 28 and 29 are diagrams schematically illustrating an arrangement of a display element according to an embodiment. FIG. 30 is a diagram schematically illustrating a display element according to an embodiment.

Herein, pixels constituting a unit pixel may also be referred to as subpixels. For example, a first pixel, a second pixel, and a third pixel constituting a unit pixel may also be referred to as a first subpixel, a second subpixel, and a third subpixel respectively.

The first pixel (first subpixel) may be a red pixel Pr that emits red light, the second pixel (second subpixel) may be a green pixel Pg that emits green light, and the third pixel (third subpixel) may be a blue pixel Pb that emits blue light. The subpixel may refer to an emission area as a minimum unit for implementing an image. When an organic light emitting diode is used as a display element, an emission area of the subpixel may be defined by an emission layer or an opening of a pixel definition layer. The pixel arrangement structure may be defined by a subpixel arrangement structure, an arrangement structure of a display element, or an arrangement structure of an emission layer.

In an embodiment, as illustrated in FIG. 28, red pixels Pr, green pixels Pg, and blue pixels Pb may be alternately arranged in each row. Red pixels Pr and blue pixels Pb may be alternately arranged in a first column M1, and green pixels Pg may be repeatedly arranged in a second column M2. Such a pixel arrangement structure may be referred to as a pentile matrix structure or a pentile structure, and high resolution may be implemented by a small number of pixels by applying a rendering drive that represents colors by sharing adjacent pixels.

FIG. 28 illustrates that a plurality of subpixels are arranged in a pentile structure; however, the disclosure is not limited thereto. For example, a plurality of subpixels may be arranged in various shapes such as a stripe arrangement structure, a diamond arrangement structure, a mosaic arrangement structure, and a delta arrangement structure.

In the stripe arrangement structure, as illustrated in FIG. 29, red pixels Pr, green pixels Pg, and blue pixels Pb may be alternately arranged in each row. Red pixels Pr may be repeatedly arranged in a first column M1, green pixels Pg may be repeatedly arranged in a second column M2, and blue pixels Pb may be repeatedly arranged in a third column M3.

Referring to FIG. 30, in an embodiment, a display element 220 may be an organic light emitting diode. The display element 220 may include a pixel electrode 221 arranged over an insulating layer IL, an opposite electrode 225 facing the pixel electrode 221, and an emission layer 223 arranged between the pixel electrode 221 and the opposite electrode 225. A first functional layer 222 may be arranged between the pixel electrode 221 and the emission layer 223, and a second functional layer 224 may be arranged between the emission layer 223 and the opposite electrode 225. The pixel electrode 221 may be connected to a pixel circuit PC.

An edge of the pixel electrode 221 may be covered with a bank layer BKL including an insulating material. The bank layer BKL may include an opening B-OP overlapping a portion of the pixel electrode 221.

The pixel electrode 221 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any compound thereof. In another embodiment, the pixel electrode 221 may further include a layer formed of ITO, IZO, ZnO, AZO, or In₂O₃ over/under the reflective layer.

The emission layer 223 may include a high-molecular weight or low-molecular weight organic material for emitting light of a certain color. The first functional layer 222 may include a hole transport layer (HTL) and/or a hole injection layer (HIL). The second functional layer 224 may include an electron transport layer (ETL) and/or an electron injection layer (EIL).

The opposite electrode 225 may include a conductive material having a low work function. For example, the opposite electrode 225 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the opposite electrode 225 may further include a layer such as ITO, IZO, ZnO, AZO, or In₂O₃ over the (semi)transparent layer including the above material.

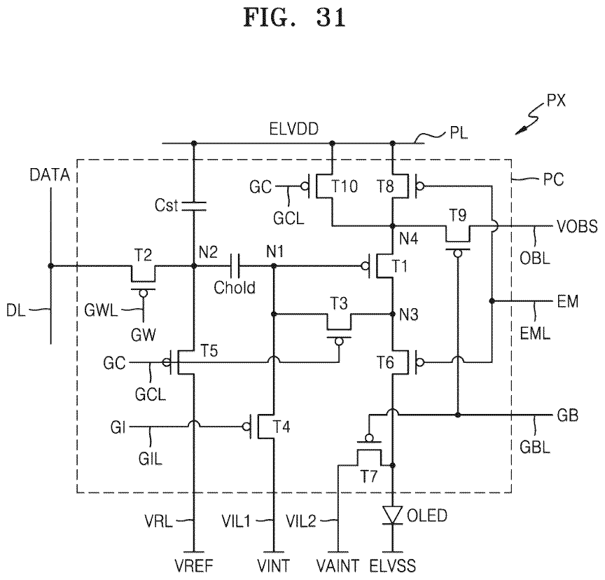

FIGS. 31 to 35 are equivalent circuit diagrams of a pixel according to an embodiment.

A pixel PX of FIG. 31 may be different from the pixel PX of FIG. 3 in that it further includes an eighth transistor T8, a ninth transistor T9, and a tenth transistor T10. Hereinafter, differences from FIG. 3 will be mainly described, and redundant descriptions of the same configurations and operations will be omitted for conciseness. The eighth transistor T8, the ninth transistor T9, and the tenth transistor T10 may be P-channel transistors.

The eighth transistor T8 may be connected between the driving voltage line PL and the first transistor T1. The eighth transistor T8 may be connected to the driving voltage line PL and a fourth node N4. The eighth transistor T8 may include a gate connected to the fourth gate line EML, a first terminal connected to the driving voltage line PL, and a second terminal connected to the first transistor T1. The eighth transistor T8 may be turned on by a fourth gate signal EM received through the fourth gate line EML. When the sixth transistor T6 and the eighth transistor T8 are simultaneously turned on by the fourth gate signal EM, a driving current may flow through the organic light emitting diode OLED.

The ninth transistor T9 may be connected between the first transistor T1 and a bias voltage line OBL. The ninth transistor T9 may be connected to the fourth node N4 and the bias voltage line OBL. The ninth transistor T9 may include a gate connected to the fifth gate line GBL, a first terminal connected to the fourth node N4, and a second terminal connected to the bias voltage line OBL. The ninth transistor T9 may be turned on by a fifth gate signal GB received through the fifth gate line GBL. The seventh transistor T7 and the ninth transistor T9 may be simultaneously turned on by the fifth gate signal GB. A second initialization voltage VAINT may be transmitted to a pixel electrode of the organic light emitting diode OLED by the turned-on seventh transistor T7, and a bias voltage VOBS may be transmitted to a first terminal of the first transistor T1 by the turned-on ninth transistor T9.

The tenth transistor T10 may be connected between the driving voltage line PL and the first transistor T1. The tenth transistor T10 may be connected to the driving voltage line PL and the fourth node N4. The tenth transistor T10 may include a gate connected to the third gate line GCL, a first terminal connected to the driving voltage line PL, and a second terminal connected to the fourth node N4. The tenth transistor T10 may be turned on by a third gate signal GC received through the third gate line GCL, and a first driving voltage ELVDD may be transmitted to the first terminal of the first transistor T1.

The gate-source voltage of the first transistor T1 may be controlled by controlling the voltage of the first terminal of the first transistor T1 by the ninth transistor T9 and the tenth transistor T10.

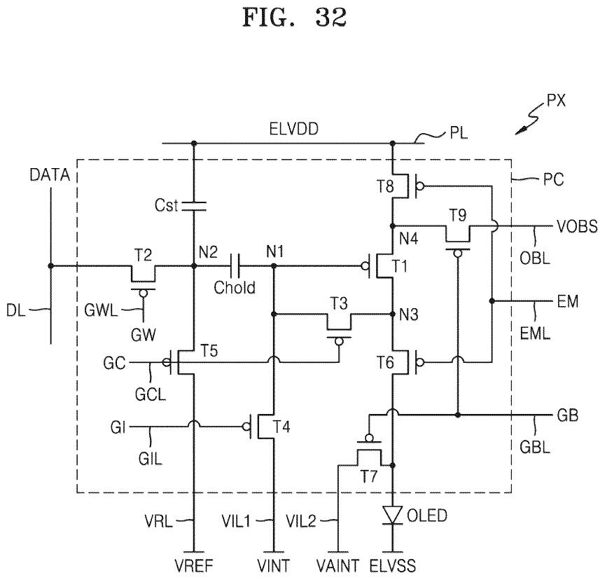

A pixel PX of FIG. 32 is similar to the pixel PX of FIG. 31 except that the tenth transistor T10 is omitted.

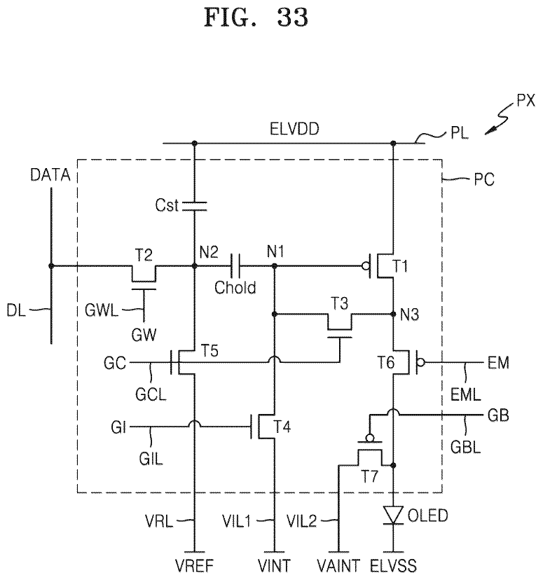

A pixel PX of FIG. 33 is similar to the pixel PX of FIG. 3 except that the second transistor T2, the third transistor T3, the fourth transistor T4, and the fifth transistor T5 are N-channel transistors. The N-channel transistor may be an oxide thin film transistor including an oxide semiconductor. The semiconductor of the oxide thin film transistor may include an oxide such as amorphous idium galium zinc oxide (IGZO), zinc oxide (ZnO), or titanium oxide (TiO).

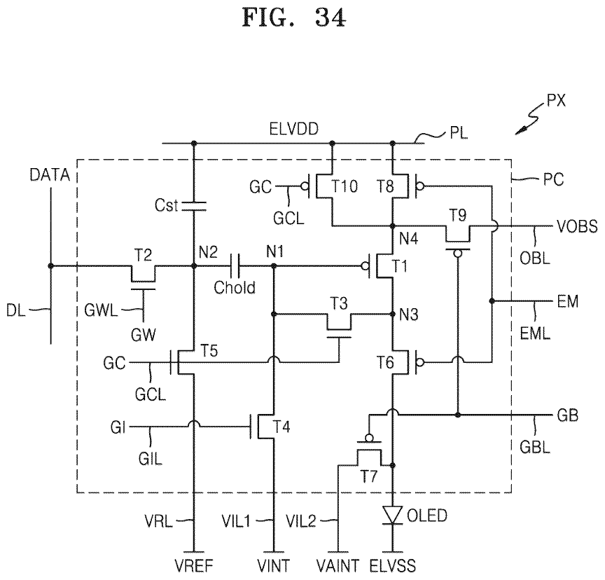

A pixel PX of FIG. 34 is similar to the pixel PX of FIG. 31 except that the second transistor T2, the third transistor T3, the fourth transistor T4, and the fifth transistor T5 are N-channel transistors.

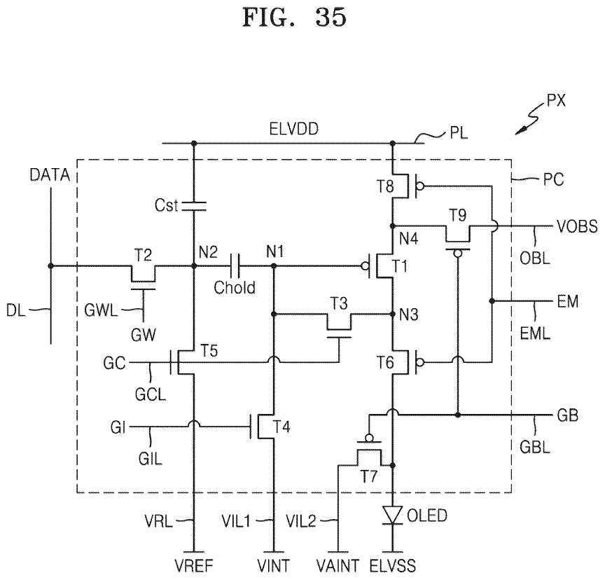

A pixel PX of FIG. 35 is similar to the pixel PX of FIG. 32 except that the second transistor T2, the third transistor T3, the fourth transistor T4, and the fifth transistor T5 are N-channel transistors.

As illustrated in FIG. 6, the pixels PX of FIGS. 31 to 35 may include a shield portion SHE between the data line DL and the reference voltage line VRL in an area in which the data line DL and the reference voltage line VRL overlap each other. A constant voltage may be supplied to the shield portion SHE.

As illustrated in FIG. 7, in the pixels PX of FIGS. 31 to 35, a vertical reference voltage line VRLv connected to the reference voltage line VRL may be spaced apart from the data line DL by a certain distance to minimize the influence of the data signal DATA. For example, the vertical reference voltage line VRLv may be arranged on the boundary between adjacent circuit areas in which the data line DL is not arranged.

As illustrated in FIG. 8, in the pixels PX of FIGS. 31 to 35, a shield portion SHE may be provided between the data line DL and the reference voltage line VRL in an area in which the data line DL and the reference voltage line VRL overlap each other, and the vertical reference voltage line VRLv may be arranged on the boundary between the first circuit area PCA1 and the second circuit area PCA2.

The present embodiments are not limited to the pixels illustrated in FIG. 3 and FIGS. 31 to 35.

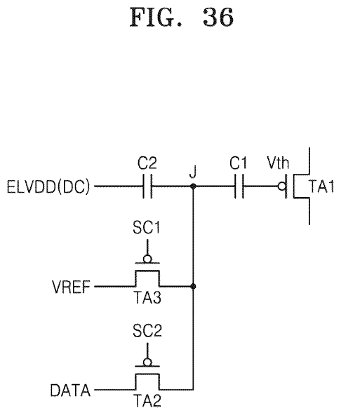

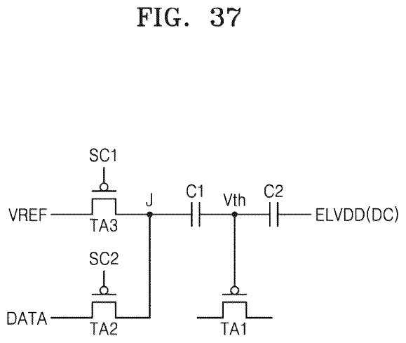

FIGS. 36 and 37 are diagrams schematically illustrating a portion of a pixel according to an embodiment.

A pixel circuit of the pixel according to an embodiment may include a first capacitor C1 and a second capacitor C2 between a voltage line for supplying a first driving voltage ELVDD that is a DC voltage (constant voltage) and a driving transistor TA1, a transistor TA2 for transmitting a data signal DATA, and a transistor TA3 for transmitting a DC voltage (e.g., a reference voltage VREF) before the data signal DATA is written into a node J where the data signal DATA is written. The transistor TA2 may be turned on or turned off by a gate signal SC2 and the transistor TA3 may be turned on or turned off by a gate signal SC1. A threshold voltage Vth of the driving transistor TA1 may be stored in the first capacitor C1.

In an embodiment, as illustrated in FIG. 36, the gate of the driving transistor TA1 may be connected to one end of the first capacitor C1, and the node J may be a node between the first capacitor C1 and the second capacitor C2. For example, the driving transistor TA1, the transistor TA2, the transistor TA3, the first capacitor C1, and the second capacitor C2 illustrated in FIG. 36 may correspond to the first transistor T1, the second transistor T2, the fifth transistor T5, the capacitor Chold, and the capacitor Cst in the pixels illustrated in FIG. 3 and FIGS. 31 to 35. The node J may correspond to the second node N2.

In an embodiment, as illustrated in FIG. 37, the gate of the driving transistor TA1 may be connected to one end of the first capacitor C1 between the first capacitor C1 and the second capacitor C2, and the node J may be a node to which the other end of the first capacitor C1 is connected.

In the pixel circuit including the circuit illustrated in FIGS. 36 and 37, a shield portion SHE overlapping the reference voltage line VRL and the data line DL and/or a vertical reference voltage line VRLv connected to the reference voltage line VRL may be arranged apart from the data line DL by a certain distance, as illustrated in FIGS. 6 to 8.

According to embodiments, in the display apparatus including the display panel in which the pixels including the pixel circuits in which the data line and the reference voltage line partially overlap each other, a signal distortion may be minimized and thus a cross-talk in the form of a horizontal line may be prevented.

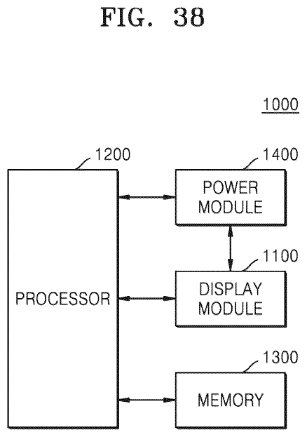

FIG. 38 is a block diagram of an electronic apparatus according to an embodiment.

Referring to FIG. 38, an electronic apparatus 1000 according to an embodiment may include a display module 1100, a processor 1200, a memory 1300, and a power module 1400.

The electronic apparatus 1000 may output various types of information in an operating system through the display module 1100.

The processor 1200 may include at least one of a central processing unit (CPU), an application processor (AP), a graphic processing unit (GPU), a communication processor (CP), an image signal processor (ISP), and a controller. In an embodiment, the processor 1200 may be divided into two or more processors from a functional or structural viewpoint. For example, the processor 1200 may include a main processor in the form of a first driving chip including a CPU, and an auxiliary processor in the form of a second driving chip including a controller that receives an image signal from the main processor and processes the image signal in accordance with the interface specifications of the display module 1100.

The memory 1300 may include at least one of a nonvolatile memory and a volatile memory. The memory 1300 may store data information necessary for the operation of the processor 1200 or the display module 1100. When the processor 1200 executes an application stored in the memory 1300, an image data signal and/or an input control signal may be transmitted to the display module 1100 and the display module 1100 may process the received signal and output image information through a display screen.

The power module 1400 may include a power supply module such as a power adapter or a battery device, and a power conversion module that converts the power supplied by the power supply module to generate power necessary for the operation of the electronic apparatus 1000. The power conversion by the power conversion module may include, but is not limited to, DC-DC conversion, AC-DC conversion, and DC-AC conversion.

At least one of the components of the electronic apparatus 1000 described above may be included in the display apparatus according to the embodiments described above. Also, some of the individual modules functionally included in one module may be included in the display apparatus, and some others thereof may be provided separately from the display apparatus. For example, the display apparatus may include the display module 1100 and an auxiliary processor of the processor 1200, and a main processor of the processor 1200, the memory 1300, and the power module 1400 may be provided in the form of other devices in the electronic apparatus 1000, not in the display apparatus. As another example, the power module 1400 may be arranged in the display apparatus and may supply power to the processor 1200 and the memory 1300 provided in the electronic apparatus 1000, not in the display apparatus; however, the disclosure is not limited thereto.

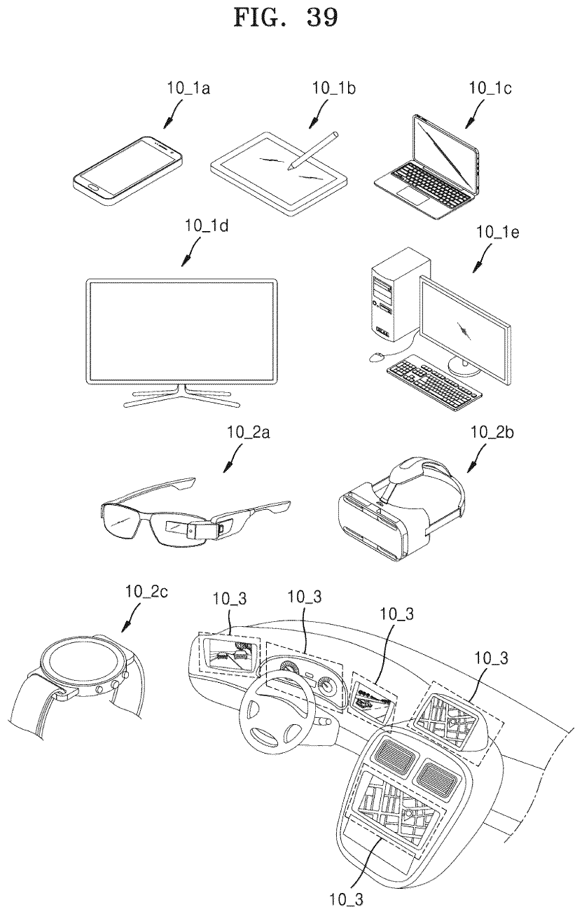

FIG. 39 is a schematic diagram of electronic apparatuses according to various embodiments.

The display apparatus according to embodiments may be an apparatus that displays moving images or still images, and may be applied to various electronic apparatuses. Referring to FIG. 39, various electronic apparatuses including the display apparatus according to embodiments may include not only an electronic apparatus for displaying images, such as a smart phone 10_1a, a tablet personal computer (PC) 10_1b, a laptop computer 10_1c, a television (TV) 10_1d, or a desk monitor 10_1e, but also a wearable electronic apparatus including a display module, such as smart glasses 10_2a, a head-mounted display 10_2b, or a smart watch 10_2c, and a vehicle electronic apparatus 10_3 including a display module, such as a center information display (CID) or a room mirror display arranged in the instrument panel, center fascia, or dashboard of a car. The electronic apparatus 1000 according to embodiments is not limited to the above apparatuses.

The electronic apparatus of FIG. 39 may include the components illustrated in FIG. 38. For example, the smart phone 10_1a may include the display module 1100, the processor 1200, the memory 1300, and the power module 1400 illustrated in FIG. 38. The smart phone 10_1a may further include a communication module and a battery device. The power provided by the battery device may be converted through the power module 1400 and provided to the processor 1200, the memory 1300, and the display module 1100. In an embodiment, the display apparatus included in the smart phone 10_1a may include the display module 1100 and may further include the power module 1400. The processor 1200 and the memory 1300 may be provided in the form of a chip mounted on a motherboard; however, the disclosure is not limited thereto.

According to embodiments, a high-resolution display apparatus without a signal distortion may be provided. However, the scope of the disclosure is not limited to these effects.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a substrate having a first circuit area and a second circuit area adjacent to the first circuit area;
a first voltage line connected to a first pixel circuit arranged in the first circuit area and a second pixel circuit arranged in the second circuit area, the first voltage line extending in a first direction;
a first data line connected to the first pixel circuit and extending in a second direction perpendicular to the first direction;
a second data line connected to the second pixel circuit and extending in the second direction; and
a shield portion arranged between the first voltage line and the first data line and overlapping the first data line and the second data line in an area where the first data line and the second data line overlap the first voltage line,
wherein, in a plan view, the first data line and the second data line are arranged apart from each other, a boundary between the first circuit area and the second circuit area extending between the first data line and the second data line and parallel to the first data line.

2. The display panel of claim 1, wherein, in a plan view, the first pixel circuit and the second pixel circuit are symmetrical with respect to the boundary between the first circuit area and the second circuit area.

3. The display panel of claim 1, further comprising a second voltage line connected to the first pixel circuit and the second pixel circuit, arranged in a layer between the first voltage line and the first data line, and extending in the first direction,
wherein the shield portion is a portion of the second voltage line, and
each of a first voltage supplied to the first voltage line and a second voltage supplied to the second voltage line is a constant voltage.

4. The display panel of claim 1, further comprising a third data line connected to a third pixel circuit arranged in a third circuit area adjacent to the first circuit area, the third data line extending in the second direction,
wherein the first voltage line is connected to the third pixel circuit,
the first circuit area is arranged between the third circuit area and the second circuit area,
in a plan view, the first data line and the third data line are arranged in parallel to and apart from each other, a driving transistor of the first pixel circuit and a driving transistor of the third pixel circuit being between the first data line and the third data line, and
in a plan view, the first data line and the second data line are arranged between a driving transistor of the first pixel circuit and a driving transistor of the second pixel circuit.

5. The display panel of claim 4, wherein, in a plan view, the first pixel circuit and the third pixel circuit are symmetrical with respect to a boundary between the first circuit area and the third circuit area.

6. The display panel of claim 4, further comprising a vertical voltage line arranged on a boundary between the first circuit area and the third circuit area and connected to the first voltage line.

7. The display panel of claim 4, further comprising at least one shared voltage line arranged in the first circuit area and the second circuit area, respectively, in a plan view and extending in the second direction,
wherein the shared voltage line is arranged on a side of at least one of the first data line and the second data line that is not occupied by the other one of the first data line and the second data line, and
the shared voltage line is connected to at least one third voltage line connected to the first pixel circuit, the second pixel circuit, and the third pixel circuit.

8. A display panel comprising:
a substrate having a first circuit area and a second circuit area adjacent to the first circuit area;
a first voltage line connected to a first pixel circuit arranged in the first circuit area and a second pixel circuit arranged in the second circuit area, the first voltage line extending in a first direction;
a first data line connected to the first pixel circuit and extending in a second direction perpendicular to the first direction;
a second data line connected to the second pixel circuit and extending in the second direction; and
a vertical voltage line arranged on a boundary between the first circuit area and the second circuit area and connected to the first voltage line,
wherein, in a plan view, a driving transistor of the first pixel circuit is arranged between the first data line and the vertical voltage line, and a driving transistor of the second pixel circuit is arranged between the vertical voltage line and the second data line.

9. The display panel of claim 8, wherein, in a plan view, the first pixel circuit and the second pixel circuit are symmetrical with respect to the boundary between the first circuit area and the second circuit area.

10. The display panel of claim 8, further comprising a third data line connected to a third pixel circuit arranged in a third circuit area adjacent to the second circuit area, the third data line extending in the second direction,
wherein the first voltage line is connected to the third pixel circuit,
the second circuit area is arranged between the first circuit area and the third circuit area, and
in a plan view, the second data line and the third data line are arranged apart from each other between a driving transistor of the second pixel circuit and a driving transistor of the third pixel circuit.

11. The display panel of claim 10, further comprising:
a first shield portion arranged between the first voltage line and the first data line and overlapping the first voltage line and the first data line; and
a second shield portion arranged between the first voltage line and the second data line and overlapping the first voltage line, the second data line, and the third data line.

12. The display panel of claim 11, further comprising a second voltage line connected to the first pixel circuit, the second pixel circuit, and the third pixel circuit, and arranged in a layer between the first voltage line and the first data line, and extending in the first direction,
wherein the first shield portion and the second shield portion are portions of the second voltage line, and
each of a first voltage supplied to the first voltage line and a second voltage supplied to the second voltage line is a constant voltage.

13. The display panel of claim 10, wherein in a plan view, the second pixel circuit and the third pixel circuit are symmetrical with respect to a boundary between the second circuit area and the third circuit area.

14. The display panel of claim 10, further comprising at least one shared voltage line in at least one of the second circuit area and the third circuit area in a plan view and extending in the second direction,
wherein the shared voltage line is arranged on a side of at least one of the second data line and the third data line that is not occupied by the other one of the second data line and the third data line, and
the shared voltage line is connected to at least one third voltage line connected to the first pixel circuit, the second pixel circuit, and the third pixel circuit.

15. The display panel of claim 1, wherein the first pixel circuit comprises:
a driving transistor;
a first transistor comprising a first terminal connected to the first data line;
a second transistor comprising a first terminal connected to the first voltage line;
a first capacitor connected between a gate electrode of the driving transistor and a second terminal of the first transistor; and
a second capacitor connected between the first capacitor and a driving voltage line,
wherein a second terminal of the second transistor is connected to a second terminal of the first transistor.

16. The display panel of claim 15, wherein the shield portion is a portion of the driving voltage line, and
each of a first voltage supplied to the first voltage line and a driving voltage supplied to the driving voltage line is a constant voltage.

17. The display panel of claim 15, wherein, after the first voltage supplied to the first voltage line is supplied through the second transistor to a node to which the second terminal of the second transistor and the second terminal of the first transistor are connected, a data signal supplied to the first data line is supplied to the node through the first transistor.

18. An electronic apparatus comprising:
a controller configured to receive an on-operation signal from a processor and output a control signal based on the on-operation signal;
a gate driver configured to receive the control signal and sequentially output at least one gate signal; and
a display panel in which a plurality of pixels receiving the at least one gate signal are arranged,
wherein each of the plurality of pixels comprises a pixel circuit and a light emitting element connected to the pixel circuit, and
the display panel comprises:
a substrate having a first circuit area and a second circuit area adjacent to the first circuit area;
a first voltage line connected to a first pixel circuit arranged in the first circuit area and a second pixel circuit arranged in the second circuit area, the first voltage line extending in a first direction;
a first data line connected to the first pixel circuit and extending in a second direction perpendicular to the first direction;
a second data line connected to the second pixel circuit and extending in the second direction; and
a shield portion arranged between the first voltage line and the first data line and overlapping the first data line and the second data line in an area where the first data line and the second data line overlap the first voltage line,
wherein, in a plan view, the first data line and the second data line are arranged apart from each other, a boundary between the first circuit area and the second circuit area extending between the first data line and the second data line and parallel to the first data line.

19. The electronic apparatus of claim 18, wherein the display panel further comprises a third data line connected to a third pixel circuit arranged in a third circuit area adjacent to the first circuit area, the third data line extending in the second direction,
wherein the first voltage line is connected to the third pixel circuit,
the first circuit area is arranged between the third circuit area and the second circuit area,
in a plan view, the first data line and the third data line are arranged parallel to and apart from each other, a driving transistor of the first pixel circuit and a driving transistor of the third pixel circuit being between the first data line and the third data line, and
in a plan view, the first data line and the second data line are arranged between a driving transistor of the first pixel circuit and a driving transistor of the second pixel circuit.

20. The electronic apparatus of claim 19, further comprising a vertical voltage line arranged on a boundary between the first circuit area and the third circuit area and connected to the first voltage line.
